(19) United States
(12) Patent Application Publication
(10) Pub. No.: US 2025/0158591 A1
(43) Pub. Date: May 15, 2025

(54) ACOUSTIC WAVE DEVICE

(71) Applicant: Murata Manufacturing Co., Ltd., Nagaokakyo-shi (JP)

(72) Inventors: Katsuya DAIMON, Nagaokakyo-shi (JP); Sho NAGATOMO, Nagaokakyo-shi (JP)

(21) Appl. No.: 19/019,947

(22) Filed: Jan. 14, 2025

Related U.S. Application Data
(63) Continuation of application No. PCT/JP2023/029612, filed on Aug. 16, 2023.
(60) Provisional application No. 63/398,608, filed on Aug. 17, 2022.

(51) Int. Cl. H03H 9/13; H03H 9/02; H03H 9/17

(52) U.S. Cl. CPC H03H 9/132; H03H 9/02031; H03H 9/02157; H03H 9/02228; H03H 9/173; H03H 9/175; H03H 9/176

(57) ABSTRACT

An acoustic wave device includes a piezoelectric layer, first and second comb-shaped electrodes each respectively including first and second busbars and first and second electrode fingers connected to the first and second busbars, and connected to input and output potentials, and a reference potential electrode connected to a reference potential and including third electrode fingers on the piezoelectric layer and aligned with the first and second electrode fingers, and a connection electrode connecting adjacent third electrode fingers. An order in which a first electrode finger, a second electrode finger, and a third electrode finger are arranged is such that, starting from the first electrode finger, the first electrode finger, the third electrode finger, the second electrode finger, and the third electrode finger define one period. A total number of the first, second, and third electrode fingers is equal to or greater than sixteen.

### CROSS REFERENCE TO RELATED APPLICATIONS

This application the benefit of priority to Provisional Application No. 63/398,608 filed on Aug. 17, 2022 and is a Continuation Application of PCT Application No. PCT/JP2023/029612 filed on Aug. 16, 2023. The entire contents of each application are hereby incorporated herein by reference.

### BACKGROUND OF THE INVENTION

### 1. Field of the Invention

The present invention relates to acoustic wave devices.

### 2. Description of the Related Art

Acoustic wave devices have heretofore been widely used in filters for mobile phones and the like. An acoustic wave device using bulk waves in a thickness-shear mode has recently been proposed, as described in U.S. Pat. No. 10,491,192. In this acoustic wave device, a piezoelectric layer is provided on a support. A pair of electrodes are provided on the piezoelectric layer. The pair of electrodes face each other on the piezoelectric layer and are connected to different potentials. An AC voltage is applied between the electrodes to excite bulk waves in the thickness-shear mode.

An acoustic wave device is, for example, an acoustic wave resonator, and is used in a ladder filter, for example. In order to obtain good characteristics in the ladder filter, the electrostatic capacitance ratio needs to be increased between a plurality of acoustic wave resonators. In this case, the electrostatic capacitances of some of the acoustic wave resonators in the ladder filter need to be increased.

In order to increase the electrostatic capacitance of the acoustic wave resonator, for example, the acoustic wave resonator needs to be increased in size. For this reason, in the case of using such an acoustic wave resonator in a ladder filter, the ladder filter tends to be increased in size. In particular, a ladder filter having an acoustic wave resonator that uses a thickness-shear mode bulk wave with a small electrostatic capacitance tends to be increased in size.

The inventors of example embodiments of the present invention have discovered that when an acoustic wave device is used in a filter device, the following configuration of the acoustic wave device can obtain a suitable filter waveform without increasing the size. In this configuration, an electrode connected to a reference potential is disposed between an electrode connected to an input potential and an electrode connected to an output potential.

The inventors of example embodiments of the present invention have also discovered that there is a possibility that simply providing the above configuration cannot sufficiently reduce insertion loss.

### SUMMARY OF THE INVENTION

Example embodiments of the present invention provide acoustic wave devices each achieving miniaturization of a filter device and reducing insertion loss.

According to an example embodiment of the present invention, an acoustic wave device includes a piezoelectric layer made of lithium niobate with Euler angles (φ, θ, ψ) within a range of Expression (1), Expression (2), or Expression (3) below, a first comb-shaped electrode on the piezoelectric layer, including a first busbar and a plurality of first electrode fingers each including one end connected to the first busbar, and being connected to an input potential, a second comb-shaped electrode on the piezoelectric layer, including a second busbar and a plurality of second electrode fingers each including one end connected to the second busbar and being interdigitated with the plurality of first electrode fingers, and being connected to an output potential, and a reference potential electrode connected to a reference potential and including a plurality of third electrode fingers on the piezoelectric layer and aligned with the first electrode fingers and the second electrode fingers in a direction in which the first electrode fingers and the second electrode fingers are arranged, and a connection electrode connecting adjacent third electrode fingers, wherein an order in which a first electrode finger, a second electrode finger, and a third electrode finger are arranged is such that, starting from the first electrode finger, the first electrode finger, the third electrode finger, the second electrode finger, and the third electrode finger define one period, and a total number of the first electrode fingers, the second electrode fingers, and the third electrode fingers is equal to or greater than sixteen,
(within a range of 0°±10°, 0° to 25°, any ψ) Expression (1);
(within a range of 0°±10°, 25° to 100°, 0° to 75° [(1-(θ-50)²/2500)]^{1/2} or 180°-75° [(1−(θ-50)²/2500)]^{1/2} to 180°) Expression (2); and
(within a range of 0°±10°, 180°-40° [(1−(ψ-90)²/8100)]^{1/2} to 180°, any ψ) Expression (3);

According to another example embodiment of the present invention, an acoustic wave device includes a piezoelectric layer made of lithium niobate, a first comb-shaped electrode on the piezoelectric layer, including a first busbar and a plurality of first electrode fingers each including one end connected to the first busbar, and being connected to an input potential, a second comb-shaped electrode on the piezoelectric layer, including a second busbar and a plurality of second electrode fingers each including one end connected to the second busbar and being interdigitated with the plurality of first electrode fingers, and being connected to an output potential, and a reference potential electrode connected to a reference potential and including a plurality of third electrode fingers on the piezoelectric layer and aligned with the first electrode fingers and the second electrode fingers in a direction in which the first electrode fingers and the second electrode fingers are arranged, and a connection electrode connecting adjacent third electrode fingers, wherein an order in which a first electrode finger, a second electrode finger, and a third electrode finger are arranged is such that, starting from the first electrode finger, the first electrode finger, the third electrode finger, the second electrode finger, and the third electrode finger define one period, a region where the first electrode finger and the second electrode finger overlap each other when viewed from a direction orthogonal or substantially orthogonal to an electrode finger extending direction in which the first electrode finger, the second electrode finger, and the third electrode finger extend is an intersection region, and Ap/px≥about 5, where Ap is an intersection width of the intersection region along the electrode finger extending direction and px is a center-to-center distance between the first electrode finger and the third electrode finger adjacent to each other or a center-to-center distance between the second electrode finger and the third electrode finger adjacent to each other.

According to an additional example embodiment of the present invention, an acoustic wave device includes a piezoelectric layer made of lithium niobate with Euler angles (φ, θ, ψ) within a range of Expression (1), Expression (2), or Expression (3, a first comb-shaped electrode on the piezoelectric layer, including a first busbar and a plurality of first electrode fingers each including one end connected to the first busbar, and being connected to an input potential, a second comb-shaped electrode on the piezoelectric layer, including a second busbar and a plurality of second electrode fingers each including one end connected to the second busbar and being interdigitated with the plurality of first electrode fingers, and being connected to an output potential, and a reference potential electrode connected to a reference potential and including a plurality of third electrode fingers on the piezoelectric layer and aligned with the first electrode fingers and the second electrode fingers in a direction in which the first electrode fingers and the second electrode fingers are arranged, and a connection electrode connecting adjacent third electrode fingers, wherein an order in which a first electrode finger, a second electrode finger, and a third electrode finger are arranged is such that, starting from the first electrode finger, the first electrode finger, the third electrode finger, the second electrode finger, and the third electrode finger define one period, when a direction in which the first electrode finger, the second electrode finger, and the third electrode finger extend is an electrode finger extending direction, leading ends of the plurality of first electrode fingers and the plurality of second electrode fingers each face an electrode connected to one of the input potential, the output potential, and the reference potential, which is different from that of the electrode fingers, across a gap in the electrode finger extending direction, and G/px≤about 0.5, where G is a gap length of each gap along the electrode finger extending direction and px is a center-to-center distance between the first electrode finger and the third electrode finger adjacent to each other or a center-to-center distance between the second electrode finger and the third electrode finger adjacent to each other,
(within a range of 0°±10°, 0° to 25°, any ψ) Expression (1);
(within a range of 0°±10°, 25° to 100°, 0° to 75° [(1-(θ-50)²/2500)]^{1/2} or 180°-75° [(1−(θ-50)²/2500)]^{1/2} to 180°) Expression (2); and
(within a range of 0°±10°, 180°-40° [(1−(ψ-90)²/8100)]^{1/2} to 180°, any ψ) Expression (3).

According to a further example embodiment of the present invention, an acoustic wave device includes a piezoelectric layer made of lithium niobate with Euler angles (φ, θ, ψ) within a range of Expression (1), Expression (2), or Expression (3) below, a first comb-shaped electrode on the piezoelectric layer and including a first busbar and a plurality of first electrode fingers each including one end connected to the first busbar, a second comb-shaped electrode on the piezoelectric layer and including a second busbar and a plurality of second electrode fingers each including one end connected to the second busbar and being interdigitated with the plurality of first electrode fingers, and a reference potential electrode connected to a reference potential and including a plurality of third electrode fingers on the piezoelectric layer and aligned with the first electrode fingers and the second electrode fingers in a direction in which the first electrode fingers and the second electrode fingers are arranged, and a connection electrode connecting adjacent third electrode fingers, wherein the first comb-shaped electrode is connected to one of an input potential and an output potential, and the second comb-shaped electrode is connected to another of the input potential and the output potential, an order in which a first electrode finger, a second electrode finger, and a third electrode finger are arranged is such that, starting from the first electrode finger, the first electrode finger, the third electrode finger, the second electrode finger, and the third electrode finger define one period, leading ends of at least some of the adjacent third electrode fingers, among all of the adjacent third electrode fingers, on a first busbar side are connected by the connection electrode, and G-B gap length≤G-F gap length, where the G-B gap length is a distance between the connection electrode connecting the leading ends of the adjacent third electrode fingers on the first busbar side and the first busbar, and the G-F gap length is a distance between the connection electrode and a leading end of the second electrode finger,
(within a range of 0°±10°, 0° to 25°, any ψ) Expression (1);
(within a range of 0°±10°, 25° to 100°, 0° to 75° [(1-(θ-50)²/2500)]^{1/2} or 180°-75° [(1−(θ-50)²/2500)]^{1/2} to 180°) Expression (2); and
(within a range of 0°±10°, 180°-40° [(1−(ψ-90)²/8100)]^{1/2} to 180°, any ψ) Expression (3);

According to an example embodiment of the present invention, an acoustic wave device includes a piezoelectric layer made of lithium niobate with Euler angles (φ, θ, ψ) (within a range of 0°±5°, within a range of −8°±14°, within a range of) 90°±5°, a first comb-shaped electrode on the piezoelectric layer, including a first busbar and a plurality of first electrode fingers each including one end connected to the first busbar, and being connected to an input potential, a second comb-shaped electrode on the piezoelectric layer, including a second busbar and a plurality of second electrode fingers each including one end connected to the second busbar and being interdigitated with the plurality of first electrode fingers, and being connected to an output potential, and a reference potential electrode connected to a reference potential and including a plurality of third electrode fingers on the piezoelectric layer and aligned with the first electrode fingers and the second electrode fingers in a direction in which the first electrode fingers and the second electrode fingers are arranged, and a connection electrode connecting adjacent third electrode fingers, wherein an order in which a first electrode finger, a second electrode finger, and a third electrode finger are arranged is such that, starting from the first electrode finger, the first electrode finger, the third electrode finger, the second electrode finger, and the third electrode finger define one period, when a direction in which the first electrode finger, the second electrode finger, and the third electrode finger extend is an electrode finger extending direction, leading ends of the plurality of first electrode fingers and the plurality of second electrode fingers each face an electrode connected to one of the input potential, the output potential, and the reference potential, which is different from that of the electrode fingers, across a gap in the electrode finger extending direction, and G/px≥ about 1, where G is a gap length of each gap along the electrode finger extending direction and px is a center-to-center distance between the first electrode finger and the third electrode finger adjacent to each other or a center-to-center distance between the second electrode finger and the third electrode finger adjacent to each other.

According to another example embodiment of the present invention, an acoustic wave device includes a piezoelectric layer made of lithium niobate with Euler angles (φ, θ, ψ) (within a range of 0°±5°, within a range of −8°±14°, within a range of) 90°±5°, a first comb-shaped electrode on the piezoelectric layer and including a first busbar and a plurality of first electrode fingers each including one end connected to the first busbar, a second comb-shaped electrode on the piezoelectric layer and including a second busbar and a plurality of second electrode fingers each including one end connected to the second busbar and being interdigitated with the plurality of first electrode fingers, and a reference potential electrode connected to a reference potential and including a plurality of third electrode fingers on the piezoelectric layer and aligned with the first electrode fingers and the second electrode fingers in a direction in which the first electrode fingers and the second electrode fingers are arranged, and a connection electrode connecting adjacent third electrode fingers, wherein the first comb-shaped electrode is connected to one of an input potential and an output potential, and the second comb-shaped electrode is connected to another of the input potential and the output potential, an order in which a first electrode finger, a second electrode finger, and a third electrode finger are arranged is such that, starting from the first electrode finger, the first electrode finger, the third electrode finger, the second electrode finger, and the third electrode finger define one period, leading ends of at least some of the adjacent third electrode fingers, among all of the adjacent third electrode fingers, on a first busbar side are connected by the connection electrode, and G-B gap length>G-F gap length, where the G-B gap length is a distance between the connection electrode connecting the leading ends of the adjacent third electrode fingers on the first busbar side and the first busbar, and the G-F gap length is a distance between the connection electrode and a leading end of the second electrode finger on the first busbar side.

Example embodiments of the present invention provide acoustic wave devices achieving miniaturization of a filter device and reducing insertion loss.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view of an acoustic wave device according to a first example embodiment of the present invention.

FIG. 2 is a schematic plan view of the acoustic wave device according to the first example embodiment of the present invention.

FIG. 3 is a schematic elevational cross-sectional view illustrating the vicinity of first to third electrode fingers in the first example embodiment of the present invention.

FIG. 4 is a diagram illustrating a map of a fractional band width with respect to Euler angles (0°, θ, ψ) of LiNbO₃ when d/p is infinitely close to 0.

FIG. 5 is a graph illustrating bandpass characteristics of an acoustic wave device according to an example embodiment of the present invention when the total number of the first to third electrode fingers is four.

FIG. 6 is a graph illustrating bandpass characteristics of an acoustic wave device according to an example embodiment of the present invention when the total number of the first to third electrode fingers is ten.

FIG. 7 is a graph illustrating bandpass characteristics of an acoustic wave device according to an example embodiment of the present invention when the total number of the first to third electrode fingers is eighty.

FIG. 8 is a graph illustrating a relationship between the total number of the first to third electrode fingers and insertion loss around 6 GHZ.

FIG. 9 is a schematic plan view of an acoustic wave device according to a first modification of the first example embodiment of the present invention.

FIG. 10 is a schematic plan view of an acoustic wave device according to a second modification of the first example embodiment of the present invention.

FIG. 11 is a graph illustrating a relationship between Ap/px and the insertion loss around 6 GHZ.

FIG. 12 is a graph illustrating a relationship between G/px and the insertion loss around 6 GHZ.

FIG. 13 is a graph illustrating a relationship between G/px and the insertion loss around 6 GHz.

FIG. 14 is a schematic plan view of an acoustic wave device according to a fifth example embodiment of the present invention.

FIG. 15A is a schematic perspective view illustrating an appearance of an acoustic wave device that uses bulk waves in a thickness-shear mode, and FIG. 15B is a plan view illustrating an electrode structure on a piezoelectric layer.

FIG. 16 is a cross-sectional view of a portion taken along line A-A in FIG. 15A.

FIG. 17A is a schematic elevational cross-sectional view for explaining a Lamb wave propagating through a piezoelectric film of an acoustic wave device, and FIG. 17B is a schematic elevational cross-sectional view for explaining a bulk wave in the thickness-shear mode propagating through a piezoelectric film of an acoustic wave device.

FIG. 18 is a diagram illustrating an amplitude direction of the thickness-shear mode bulk wave.

FIG. 19 is a graph illustrating resonance characteristics of an acoustic wave device using the thickness-shear mode bulk wave.

FIG. 20 is a graph illustrating a relationship between d/p and a fractional band width of a resonator, where p is the center-to-center distance between adjacent electrodes and d is the thickness of the piezoelectric layer.

FIG. 21 is a plan view of an acoustic wave device using the thickness-shear mode bulk wave.

FIG. 22 is a diagram illustrating resonance characteristics of the acoustic wave device in a reference example where a spurious response appears.

FIG. 23 is a diagram illustrating a relationship between a fractional band width and a phase rotation amount of a spurious impedance normalized by about 180 degrees as a magnitude of spurious.

FIG. 24 is a diagram illustrating a relationship between d/2p and a metallization ratio MR.

FIG. 25 is a diagram illustrating a map of the fractional band width with respect to Euler angles (0°, θ, ψ) of LiNbO₃ when d/p is infinitely close to 0.

FIG. 26 is an elevational cross-sectional view of an acoustic wave device according to an example embodiment of the present invention including an acoustic multilayer film.

FIG. 27 is a partially cutaway perspective view for explaining an acoustic wave device according to an example embodiment of the present invention that excites a Lamb wave.

### DETAILED DESCRIPTION OF THE EXAMPLE EMBODIMENTS

The present invention will be clarified below by describing specific example embodiments of the present invention with reference to the drawings.

The example embodiments described in this specification are illustrative, and partial substitutions or combinations of configurations is possible between different example embodiments.

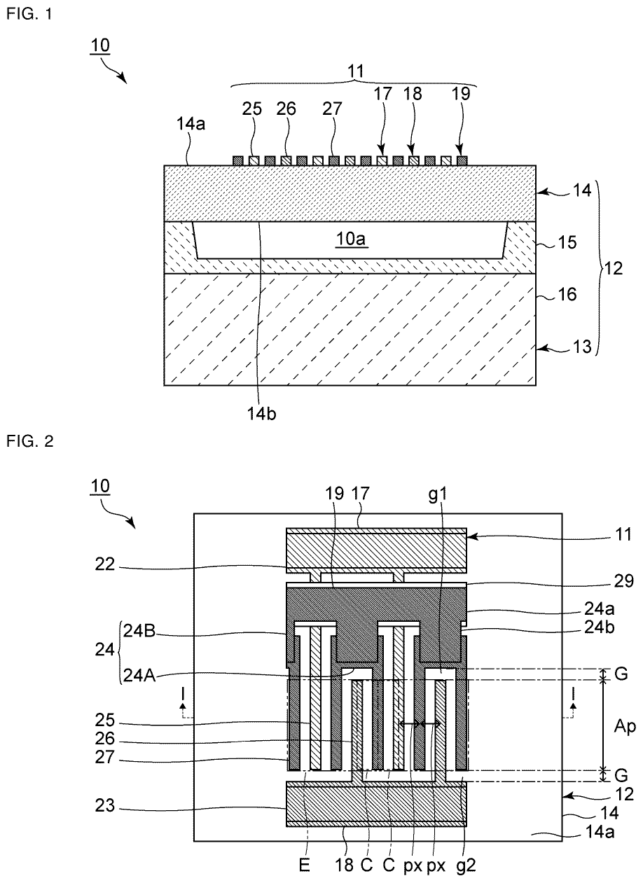

FIG. 1 is a schematic elevational cross-sectional view of an acoustic wave device according to a first example embodiment of the present invention. FIG. 2 is a schematic plan view of the acoustic wave device according to the first example embodiment. FIG. 1 is a schematic cross-sectional view taken along line I-I in FIG. 2. In FIG. 2, each electrode is illustrated with hatching. Electrodes may also be hatched in schematic plan views other than FIG. 2.

An acoustic wave device 10 illustrated in FIG. 1 is structured to excite a thickness-shear mode. The acoustic wave device 10 is an acoustically coupled filter. The configuration of the acoustic wave device 10 will be described below.

The acoustic wave device 10 includes a piezoelectric substrate 12 and a functional electrode 11. The piezoelectric substrate 12 is a substrate having piezoelectricity. Specifically, the piezoelectric substrate 12 includes a support 13 and a piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. However, the support 13 may include the support substrate 16 only. The support 13 does not necessarily have to be provided.

The piezoelectric layer 14 includes a first main surface 14a and a second main surface 14b. The first main surface 14a and the second main surface 14b face each other. Of the first main surface 14a and the second main surface 14b, the second main surface 14b is located on the support 13 side.

A functional electrode 11 is provided on the first main surface 14a of the piezoelectric layer 14. As illustrated in FIG. 2, the functional electrode 11 includes a pair of comb-shaped electrodes and a reference potential electrode 19. The reference potential electrode 19 is connected to a reference potential. The pair of comb-shaped electrodes include a first comb-shaped electrode 17 and a second comb-shaped electrode 18. The first comb-shaped electrode 17 is connected to an input potential. The second comb-shaped electrode 18 is connected to an output potential.

The first comb-shaped electrode 17 may be connected to the output potential. The second comb-shaped electrode 18 may be connected to the input potential. Therefore, the first comb-shaped electrode 17 may be connected to one of the input potential and the output potential. The second comb-shaped electrode 18 may be connected to the other of the input potential and the output potential.

The first comb-shaped electrode 17 and the second comb-shaped electrode 18 are provided on the first main surface 14a of the piezoelectric layer 14. The first comb-shaped electrode 17 includes a first busbar 22 and a plurality of first electrode fingers 25. The plurality of first electrode fingers 25 each include one end connected to the first busbar 22. The second comb-shaped electrode 18 includes a second busbar 23 and a plurality of second electrode fingers 26. The plurality of second electrode fingers 26 each include one end connected to the second busbar 23.

The first busbar 22 and the second busbar 23 face each other. The plurality of first electrode fingers 25 and the plurality of second electrode fingers 26 are interdigitated with each other. The first electrode fingers 25 and the second electrode fingers 26 are alternately arranged in a direction orthogonal or substantially orthogonal to a direction in which the first electrode fingers 25 and the second electrode fingers 26 extend.

The reference potential electrode 19 includes a third busbar 24 as a connection electrode and a plurality of third electrode fingers 27. The plurality of third electrode fingers 27 are provided on the first main surface 14a of the piezoelectric layer 14. The plurality of third electrode fingers 27 are electrically connected to each other by the third busbar 24.

The third electrode fingers 27 are aligned with the first electrode fingers 25 and the second electrode fingers 26 in a direction in which the first electrode fingers 25 and the second electrode fingers 26 are arranged. Thus, the first electrode fingers 25, the second electrode fingers 26, and the third electrode fingers 27 are arranged in one direction. The plurality of third electrode fingers 27 extend parallel or substantially parallel to the plurality of first electrode fingers 25 and the plurality of second electrode fingers.

Hereinafter, the direction in which the first electrode fingers 25, the second electrode fingers 26, and the third electrode fingers 27 extend will be referred to as an electrode finger extending direction, and the direction orthogonal or substantially orthogonal to the electrode finger extending direction will be referred to as an electrode finger orthogonal direction. When the direction in which the first electrode fingers 25, the second electrode fingers 26, and the third electrode fingers 27 are arranged is defined as an electrode finger arrangement direction, the electrode finger arrangement direction is parallel or substantially parallel to the electrode finger orthogonal direction. In this specification, the first electrode fingers 25, the second electrode fingers 26, and the third electrode fingers 27 may be collectively referred to simply as electrode fingers. The first busbar 22 and the second busbar 23 may be collectively referred to simply as busbars.

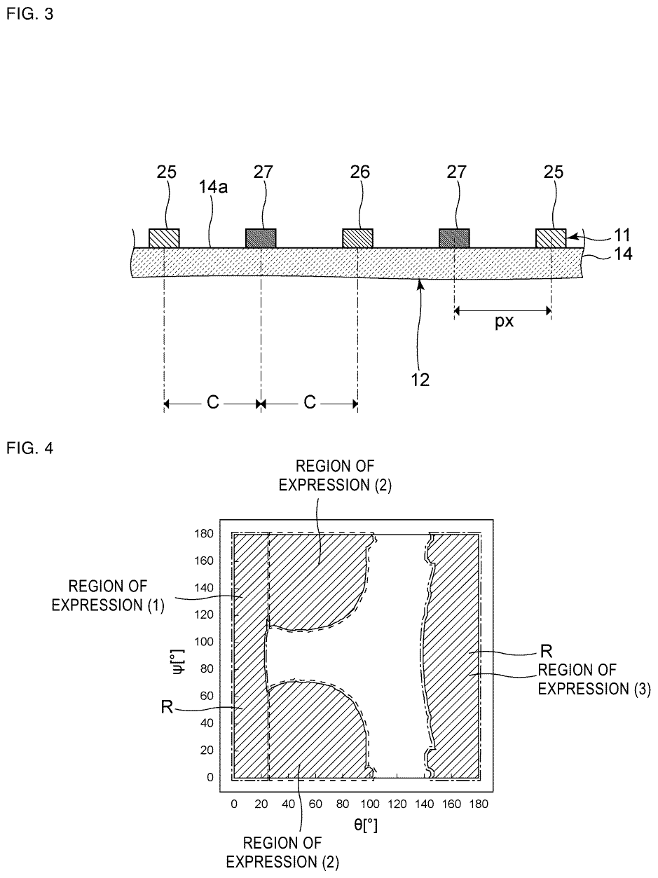

FIG. 3 is a schematic elevational cross-sectional view illustrating the vicinity of the first to third electrode fingers in the first example embodiment.

The plurality of electrode fingers are arranged as follows. Specifically, starting from the first electrode finger 25, one period includes the first electrode finger 25, the third electrode finger 27, the second electrode finger 26, and the third electrode finger 27. Therefore, the order in which the plurality of electrode fingers are arranged is the first electrode finger 25, the third electrode finger 27, the second electrode finger 26, the third electrode finger 27, the first electrode finger 25, the third electrode finger 27, the second electrode finger 26, . . . and so on. The order of the plurality of electrode fingers is represented as the order of the potentials to be connected, IN, GND, OUT, GND, IN, GND, OUT, . . . and so on, where IN represents the input potential, OUT represents the output potential, and GND represents the reference potential.

In the present example embodiment, in the region where the plurality of electrode fingers are provided, the electrode fingers located at both end portions in the electrode finger orthogonal direction are the third electrode fingers 27. In the region, the electrode fingers located at the end portions in the electrode finger orthogonal direction may be any kind of the first electrode fingers 25, the second electrode fingers 26, and the third electrode fingers 27.

As illustrated in FIG. 2, the third busbar 24 as the connection electrode for the reference potential electrode 19 electrically connects the plurality of third electrode fingers 27 to each other. Specifically, the third busbar 24 is located in a region between the first busbar 22 and leading ends of the plurality of second electrode fingers 26. The plurality of first electrode fingers 25 are also located in this region. The third busbar 24 and the plurality of first electrode fingers 25 are electrically insulated from each other by the insulating film 29.

More specifically, the third busbar 24 includes a plurality of first connection electrodes 24A and one second connection electrode 24B. Each of the first connection electrodes 24A connects leading ends of two adjacent third electrode fingers 27. The first connection electrode 24A and the two third electrode fingers 27 form a U-shaped electrode. The second connection electrode 24B connects the plurality of first connection electrodes 24A to each other. The insulating film 29 is provided between this second connection electrode 24B and the plurality of first electrode fingers 25.

To be more specific, the insulating film 29 is provided on the first main surface 14a of the piezoelectric layer 14 so as to partially cover the plurality of first electrode fingers 25. The insulating film 29 is provided in the region between the first busbar 22 and the leading ends of the plurality of second electrode fingers 26. The insulating film 29 has a strip shape.

The insulating film 29 does not extend to the first connection electrode 24A of the reference potential electrode 19. The second connection electrode 24B is provided on the insulating film 29 and over the plurality of first connection electrodes 24A. Specifically, the second connection electrode 24B includes a bar portion 24a and a plurality of protrusions 24b. Each protrusion 24b extends from the bar portion 24a toward a corresponding one of the first connection electrodes 24A. Each protrusion 24b is connected to a corresponding one of the first connection electrodes 24A. The third electrode fingers 27 are thus electrically connected to each other by the first connection electrode 24A and the second connection electrode 24B.

In the present example embodiment, the third busbar 24 is located in the region between the first busbar 22 and the leading ends of the plurality of second electrode fingers 26. Therefore, the leading ends of the plurality of second electrode fingers 26 face the third busbar 24 with a gap g1 therebetween in the electrode finger extending direction. On the other hand, the leading ends of the plurality of first electrode fingers 25 face the second busbar 23 with a gap g2 therebetween in the electrode finger extending direction.

The third busbar 24 may be located in a region between the second busbar 23 and the leading ends of the plurality of first electrode fingers 25. In this case, the leading ends of the plurality of first electrode fingers 25 each face the third busbar 24 with a gap therebetween. On the other hand, the leading ends of the plurality of second electrode fingers 26 face the first busbar 22 with a gap therebetween.

As described above, example embodiments of the present invention may be configured as follows. The leading ends of the plurality of first electrode fingers 25 may each face an electrode connected to one of the input potential, the output potential, and the reference potential, which is different from that of the first electrode fingers, across a gap in the electrode finger extending direction. Similarly, the leading ends of the plurality of second electrode fingers 26 may each face an electrode connected to one of the input potential, the output potential, and the reference potential, which is different from that of the second electrode fingers, across a gap in the electrode finger extending direction.

The dimension of these gaps along the electrode finger extending direction will be referred to as a gap length. In the present example embodiment, a gap g1 has the same gap length G as a gap g2. However, the gap length G of the gap g1 and the gap length G of the gap g2 may be different from each other.

The acoustic wave device 10 is an acoustic wave resonator configured to excite a thickness-shear mode bulk wave. As illustrated in FIG. 2, the acoustic wave device 10 includes a plurality of excitation regions C. In the plurality of excitation regions C, the thickness-shear mode bulk waves and acoustic waves in other modes are excited. FIG. 2 illustrates only two of the plurality of excitation regions C.

Some of the plurality of excitation regions C are regions where the adjacent first electrode finger 25 and third electrode finger 27 overlap when viewed from the electrode finger orthogonal direction, and also regions between the centers of the adjacent first electrode finger 25 and third electrode finger 27. The rest of the excitation regions C are regions where the adjacent second electrode finger 26 and third electrode finger 27 overlap when viewed from the electrode finger orthogonal direction, and also regions between the centers of the adjacent second electrode finger 26 and third electrode finger 27. These excitation regions C are arranged in the electrode finger orthogonal direction.

The configuration of the functional electrode 11, except for the reference potential electrode 19, is the same or substantially the same as that of an interdigital transducer (IDT) electrode. When viewed from the electrode finger orthogonal direction, the region where the adjacent first electrode finger 25 and second electrode finger 26 overlap each other is an intersection region E. However, the intersection region E can also be a region where the adjacent first electrode finger 25 and third electrode finger 27 or the adjacent second electrode finger 26 and third electrode finger 27 overlap each other when viewed from the electrode finger orthogonal direction. The intersection region E includes a plurality of excitation regions C. The intersection region E and the excitation region C are regions of the piezoelectric layer 14 defined based on the configuration of the functional electrode 11.

Hereinafter, the dimension of the intersection region E along the electrode finger extending direction will be referred to as an intersection width Ap. px is the center-to-center distance between the adjacent first electrode finger 25 and third electrode finger 27 or the center-to-center distance between the adjacent second electrode finger 26 and third electrode finger 27. In the present example embodiment, the center-to-center distance px between a plurality of pairs of first electrode fingers 25 and third electrode fingers 27 adjacent to each other is the same as the center-to-center distance px between a plurality of pairs of second electrode fingers 26 and third electrode fingers 27 adjacent to each other.

However, the center-to-center distance px between the adjacent first electrode finger 25 and third electrode finger 27 and the center-to-center distance px between the adjacent second electrode finger 26 and third electrode finger 27 do not have to be constant. In this case, p is the longest distance of the center-to-center distance px between the adjacent first electrode finger 25 and third electrode finger 27 and the center-to-center distance px between the adjacent second electrode finger 26 and third electrode finger 27. When the center-to-center distance px is constant as in the present example embodiment, the center-to-center distance px between any adjacent electrode fingers is also the distance p.

In the present example embodiment, the piezoelectric layer 14 is, for example, a lithium niobate layer. Specifically, for example, the piezoelectric layer 14 is made of rotated Y-cut LiNbO₃. In this case, the fractional band width of the acoustic wave device 10 depends on the Euler angles (φ, θ, ψ) of the lithium niobate used in the piezoelectric layer 14. The fractional band width is expressed by (|fa-fr|/fr)×100 [%], where fr is the resonant frequency and fa is the anti-resonant frequency.

The relationship between the fractional band width of the acoustic wave device 10 and the Euler angles (φ, θ, ψ) of the piezoelectric layer 14 when d/p is infinitely close to 0 is derived. Note that φ in the Euler angles is set to 0°.

FIG. 4 is a diagram illustrating a map of a fractional band width with respect to the Euler angles (0°, θ, ψ) of LiNbO₃ when d/p is infinitely close to 0.

A hatched region R in FIG. 4 is a region where the fractional band width of, for example, at least equal to or greater than about 2% is obtained. The range of the region R is approximated by the following Expressions (1), (2), and (3). When (in the Euler angles (φ, θ, ψ) is within the range of 0°±10°, the relationship between θ and ψ and the fractional band width is the same as that illustrated in FIG. 4. Also in the case where the piezoelectric layer 14 is a lithium tantalate layer, when Euler angles (θ, ψ) are within the range of 0°±10°, the relationship between θ and ψ and the fractional band width is the same as that illustrated in FIG. 4.
(within a range of 0°±10°, 0° to 25°, any ψ) Expression (1);
(within a range of 0°±10°, 25° to 100°, 0° to 75° [(1-(θ-50)²/2500)]^{1/2} or 180°-75° [(1−(θ-50)²/2500)]^{1/2} to 180°) Expression (2); and
(within a range of 0°±10°, 180°-40° [(1−(ψ-90)²/8100)]^{1/2} to 180°, any ψ) Expression (3);

It is preferable that the Euler angles are within the range of Expression (1), Expression (2), or Expression (3). This allows the fractional band width to be sufficiently widened, thus making it possible to suitably use the acoustic wave device 10 in a filter device.

The present example embodiment has the following configuration. 1) The Euler angles (φ, θ, ψ) of the piezoelectric layer 14 are within the range of Expression (1), Expression (2), or Expression (3) described above. 2) The third electrode fingers 27 of the reference potential electrode 19 are provided between the first electrode fingers 25 of the first comb-shaped electrode 17 and the second electrode fingers 26 of the second comb-shaped electrode 18. 3) The total number of the first electrode fingers 25, the second electrode fingers 26, and the third electrode fingers 27 is, for example, equal to or greater than sixteen. This makes it possible to achieve miniaturization of a filter device and reduce the insertion loss when the acoustic wave device 10 is used in the filter device. This will be described below.

The filter characteristics are compared by changing the total number of the first electrode fingers 25, the second electrode fingers 26, and the third electrode fingers 27. The acoustic wave devices in this comparison also include an acoustic wave device in which the total number of first electrode fingers 25, second electrode fingers 26, and third electrode fingers 27 is less than sixteen. Specifically, the total number of the plurality of electrode fingers is changed in increments of two within a range of four to eighty. When the total number of the plurality of electrode fingers is four, the order of potentials to be connected to the plurality of electrode fingers is GND, IN, GND, and OUT. However, this order is essentially the same as IN, GND, OUT, and GND. The design parameters of the acoustic wave devices in this comparison are as follows:
Piezoelectric layer
Material: LiNbO₃
Euler angles (φ, θ, ψ): (0°, 0°, 90°)
Thickness: about 400 nm
First to third electrode fingers
Layer structure: Ti layer/AlCu layer/Ti layer from the piezoelectric layer side
Thickness of each layer: about 10 nm/about 390 nm/about 4 nm from the piezoelectric layer side

Order of the first to third electrode fingers expressed by the potential to be connected: IN, GND, OUT, and GND are repeated in this order, or GND, IN, GND, and OUT.
Center-to-center distance px between adjacent electrode fingers: about 1.4 μm
Duty ratio of functional electrode: about 0.3
Intersection width Ap: about 40 μm
Total number of first to third electrode fingers: changed in increments of 2 within a range of 4 to 80

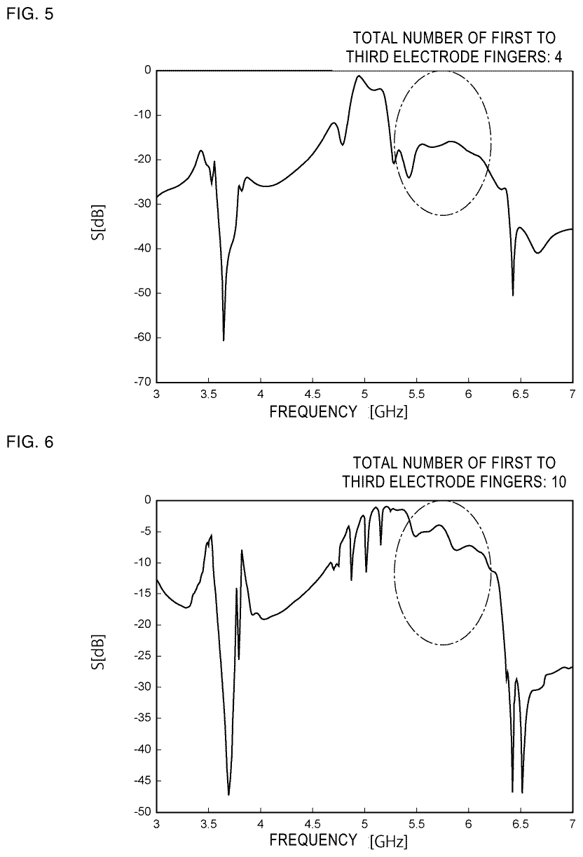

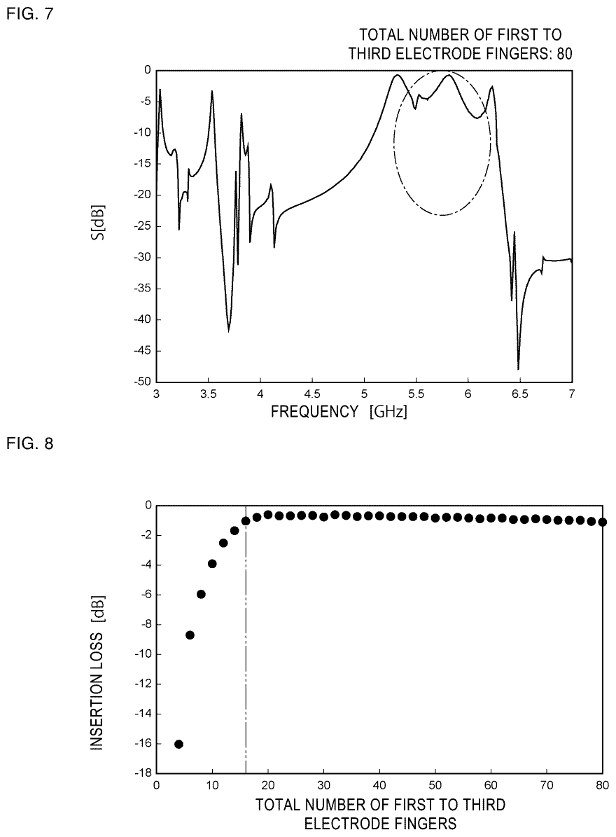

FIG. 5 is a graph illustrating bandpass characteristics of the acoustic wave device when the total number of the first to third electrode fingers is four. FIG. 6 is a graph illustrating bandpass characteristics of the acoustic wave device when the total number of the first to third electrode fingers is ten. FIG. 7 is a graph illustrating bandpass characteristics of the acoustic wave device when the total number of the first to third electrode fingers is eighty.

As illustrated in FIG. 5, a filter waveform can be obtained with one acoustic wave device even when the total number of the electrode fingers is four. However, in FIG. 5, the insertion loss is large at about 5.5 GHZ to about 6 GHZ, for example, which is surrounded by a dashed line. As illustrated in FIG. 6, the insertion loss is large at about 5.5 GHZ to about 6 GHz, for example, also when the total number of the plurality of electrode fingers is ten. On the other hand, as can be seen from FIG. 7, when the total number of the plurality of electrode fingers is eighty, a filter waveform can be suitably obtained and the insertion loss can be reduced at about 5.5 GHZ to about 6 GHz, for example.

FIG. 8 is a graph illustrating a relationship between the total number of the first to third electrode fingers and the insertion loss around 6 GHZ.

As can be seen from FIG. 8, when the total number of the plurality of electrode fingers is less than or equal to sixteen, the larger the total number of the plurality of electrode fingers, the smaller the insertion loss. It can also be seen that, when the total number of the plurality of electrode fingers is equal to or greater than sixteen, the insertion loss can be effectively reduced. In addition, when the total number of the plurality of electrode fingers is equal to or greater than sixteen, the insertion loss does not change significantly.

As described above, a filter waveform can be suitably obtained even with a single acoustic wave device 10 of the present example embodiment. This is because the acoustic wave device 10 is an acoustically coupled filter. More specifically, as illustrated in FIG. 2, the acoustic wave device 10 includes an excitation region C located between the centers of the adjacent first electrode finger 25 and third electrode finger 27, and an excitation region C located between the centers of the adjacent second electrode finger 26 and third electrode finger 27. In these excitation regions C, acoustic waves in a plurality of modes including a thickness-shear mode bulk wave are excited. By coupling these modes, a filter waveform can be suitably obtained even with a single acoustic wave device 10.

When the acoustic wave device 10 is used as an acoustic wave resonator in a filter device, a suitable filter waveform can be obtained even with one or a small number of acoustic wave resonators that constitute the filter device. This makes it possible to achieve the miniaturization of the filter device.

In addition, in the present example embodiment, the total number of the first electrode fingers 25, the second electrode fingers 26, and the third electrode fingers 27 is, for example, equal to or greater than sixteen. This makes it possible to reduce the insertion loss, as illustrated in FIG. 8.

The configuration of the first example embodiment will be described in more detail below.

As illustrated in FIG. 1, the support 13 includes the support substrate 16 and the insulating layer 15. The piezoelectric substrate 12 is a multilayer body of the support substrate 16, the insulating layer 15, and the piezoelectric layer 14. Specifically, the piezoelectric layer 14 and the support 13 overlap when viewed from the direction in which the first main surface 14a and the second main surface 14b of the piezoelectric layer 14 face each other.

Examples of the material of the support substrate 16 include a semiconductor such as silicon, ceramics such as aluminum oxide, and the like. The insulating layer 15 can be made of an appropriate dielectric such as, for example, silicon oxide or tantalum oxide.

The insulating layer 15 includes a recess portion. The piezoelectric layer 14 is provided on the insulating layer 15 so as to close the recess portion. A hollow portion is thus provided. This hollow portion is a cavity 10a. In the first example embodiment, the support 13 and the piezoelectric layer 14 are disposed so that a portion of the support 13 and a portion of the piezoelectric layer 14 face each other across the cavity 10a. However, the recess portion in the support 13 may be provided across the insulating layer 15 and the support substrate 16. Alternatively, a recess portion provided only in the support substrate 16 may be closed by the insulating layer 15. The recess portion may be provided in the piezoelectric layer 14. The cavity 10a may be a through-hole provided in the support 13.

The cavity 10a is an acoustic reflection portion. The acoustic reflection portion can effectively confine the energy of the acoustic wave to the piezoelectric layer 14 side. The acoustic reflection portion may be provided at a position on the support 13 that overlaps at least a portion of the functional electrode 11 in plan view. More specifically, the first electrode finger 25, the second electrode finger 26, and the third electrode finger 27 may each at least partially overlap with the acoustic reflection portion in plan view. In plan view, a plurality of excitation regions C preferably overlap with the acoustic reflection portion.

In this specification, a plan view refers to a view along the lamination direction of the support 13 and the piezoelectric layer 14 from a direction corresponding to the upper side in FIG. 1. In FIG. 1, for example, of the support substrate 16 side and the piezoelectric layer 14 side, the piezoelectric layer 14 side is the upper side. Furthermore, in this specification, the plan view is synonymous with a view from a main surface facing direction. The main surface facing direction is a direction in which the first main surface 14a and the second main surface 14b of the piezoelectric layer 14 face each other. More specifically, the main surface facing direction is, for example, a normal or substantially normal direction of the first main surface 14a.

The acoustic reflection portion may be an acoustic reflection film such as, for example, an acoustic multilayer film, which will be described later. For example, the acoustic reflection film may be provided on the surface of the support.

As described above, p is the longest distance of the center-to-center distance px between the adjacent first electrode finger 25 and third electrode finger 27 and the center-to-center distance px between the adjacent second electrode finger 26 and third electrode finger 27. In this case, for example, d/p is preferably less than or equal to about 0.5, more preferably less than or equal to about 0.24, where d is the thickness of the piezoelectric layer 14. This allows for better excitation of the thickness-shear mode bulk wave.

Acoustic wave devices according to example embodiments of the present invention do not necessarily have to be configured to be able to use the thickness-shear mode. For example, an acoustic wave device according to an example embodiment of the present invention may be configured to be able to excite a plate wave. In this case, the excitation region is the intersection region E illustrated in FIG. 2.

As illustrated in FIG. 2, in the first example embodiment, the reference potential electrode 19 includes the third busbar 24 as a connection electrode and the plurality of third electrode fingers 27. The reference potential electrode 19 is a comb-shaped electrode. However, the reference potential electrode 19 does not have to be a comb-shaped electrode. The present example will be described below in first modification and second modification.

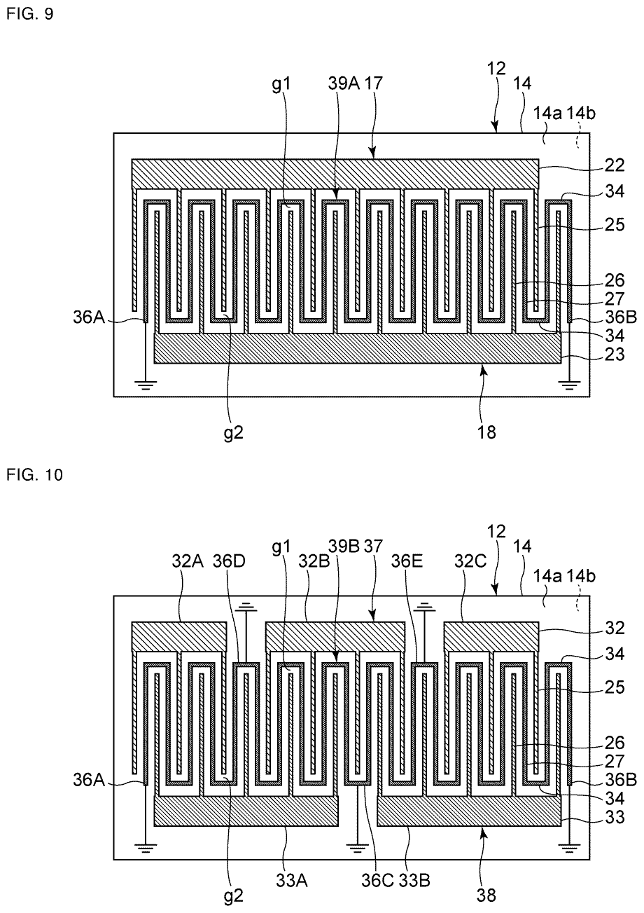

FIG. 9 is a schematic plan view of an acoustic wave device according to a first modification of the first example embodiment. In FIG. 9, a reference potential symbol is used to schematically illustrate that a reference potential electrode is connected to a reference potential. Similarly, in schematic plan views other than FIG. 9, the reference potential symbol may be used.

A reference potential electrode 39A in the present modification has a meandering shape. In the present modification, the insulating film 29 is not provided on the piezoelectric layer 14. A connection electrode 34 includes only a portion corresponding to the plurality of first connection electrodes 24A in the first example embodiment. The connection electrode 34 in the present modification is not a third busbar.

More specifically, the reference potential electrode 39A includes a plurality of connection electrodes 34 located on the first busbar 22 side and a plurality of connection electrodes 34 located on the second busbar 23 side. The leading ends of two adjacent third electrode fingers 27 on the first busbar 22 side or the leading ends of two adjacent third electrode fingers 27 on the second busbar 23 side are connected to each other by the connection electrode 34.

For example, among the plurality of third electrode fingers 27, the third electrode fingers 27 other than those at both ends in the electrode finger orthogonal direction include respective connection electrodes 34 connected to the leading ends on the first busbar 22 side and the leading ends on the second busbar 23 side. Each third electrode finger 27 is connected to its neighboring third electrode fingers 27 by the connection electrodes 34. By repeating this structure, the reference potential electrode 39A is configured into a meandering shape.

In the present modification, the leading ends of the plurality of second electrode fingers 26 face the plurality of connection electrodes 34 across a gap g1 in the electrode finger extending direction. Specifically, the leading ends of the plurality of second electrode fingers 26 each face an electrode connected to one of the input potential, the output potential, and the reference potential, which is different from that of the electrode fingers, across the gap g1 in the electrode finger extending direction. More specifically, the second electrode fingers 26 are connected to the output potential, and the connection electrodes 34 are connected to the reference potential. The dimension of the gap g1 between the leading end of the second electrode finger 26 and the connection electrode 34 along the electrode finger extending direction is the gap length G.

Similarly, the leading ends of the plurality of first electrode fingers 25 face the plurality of connection electrodes 34 across a gap g2 in the electrode finger extending direction. Specifically, the leading ends of the plurality of first electrode fingers 25 each face an electrode connected to one of the input potential, the output potential, and the reference potential, which is different from that of the electrode fingers, across the gap g2 in the electrode finger extending direction. More specifically, the first electrode fingers 25 are connected to the input potential, and the connection electrodes 34 are connected to the reference potential. The dimension of the gap g2 between the leading end of the first electrode finger 25 and the connection electrode 34 along the electrode finger extending direction is the gap length G.

In the present modification, the gap length G of the gap g1 is the same or substantially the same as the gap length G of the gap g2. However, the gap length G of the gap g1 and the gap length G of the gap g2 may be different from each other.

The portion of the reference potential electrode 39A that is connected to the reference potential is a potential connection portion. Specifically, the reference potential electrode 39A includes two potential connection portions. The two potential connection portions of the reference potential electrode 39A are, specifically, a first potential connection portion 36A and a second potential connection portion 36B.

The first potential connection portion 36A is located at the third electrode finger 27 on one end in the electrode finger orthogonal direction, among the plurality of third electrode fingers 27. More specifically, the first potential connection portion 36A is configured as a portion of the third electrode finger 27. Although not illustrated, at least one connection wiring is provided on the first main surface 14a of the piezoelectric layer 14. The first potential connection portion 36A is connected to the connection wiring. The first potential connection portion 36A is connected to the reference potential through the connection wiring.

As described above, the first potential connection portion 36A is located at the third electrode finger 27 on one end in the electrode finger orthogonal direction, among the plurality of third electrode fingers 27. On the other hand, the second potential connection portion 36B is located at the third electrode finger 27 on the other end in the electrode finger orthogonal direction, among the plurality of third electrode fingers 27. The second potential connection portion 36B is connected to the reference potential through the connection wiring.

At least one connection wiring may be provided. Specifically, one connection wiring may be connected to both the first potential connection portion 36A and the second potential connection portion 36B. Alternatively, one of the two connection wirings may be connected to the first potential connection portion 36A. The other connection wiring may be connected to the second potential connection portion 36B.

In the present modification, two of the plurality of third electrode fingers 27 at both ends in the electrode finger orthogonal direction are located at the outer side in the electrode finger orthogonal direction than both end portions of the second comb-shaped electrode 18 in the electrode finger orthogonal direction. The connection wiring connected to the first potential connection portion 36A and the second potential connection portion 36B passes the outer side in the electrode finger orthogonal direction than the both end portions of the second comb-shaped electrode 18.

In the present modification, again, the Euler angles of the piezoelectric layer 14 are the same or substantially the same as in the first example embodiment. The order in which the plurality of electrode fingers are arranged is such that, starting from the first electrode finger 25, one period includes the first electrode finger 25, the third electrode finger 27, the second electrode finger 26, and the third electrode finger 27. The total number of the first electrode fingers 25, the second electrode fingers 26, and the third electrode fingers 27 is, for example, equal to or greater than sixteen. This makes it possible to achieve miniaturization of a filter device and reduce insertion loss when the acoustic wave device is used in the filter device.

FIG. 10 is a schematic plan view of an acoustic wave device according to a second modification of the first example embodiment.

A reference potential electrode 39B of the present modification includes five potential connection portions. Each potential connection portion is connected to the reference potential through a connection wiring. The reference potential electrode 39B has a meandering shape, as in the first modification. In the present modification, both of a first busbar 32 and a second busbar 33 are divided into a plurality of split busbar portions. The connection wiring passes between the split busbar portions.

Specifically, the first busbar 32 of the first comb-shaped electrode 37 includes a split busbar portion 32A, a split busbar portion 32B, and a split busbar portion 32C. The split busbar portion 32A and the split busbar portion 32B face each other across a gap in the electrode finger orthogonal direction. The split busbar portion 32B and the split busbar portion 32C face each other across a gap in the electrode finger orthogonal direction.

The second busbar 33 of the second comb-shaped electrode 38 includes a split busbar portion 33A and a split busbar portion 33B. The split busbar portion 33A and the split busbar portion 33B face each other across a gap in the electrode finger orthogonal direction.

The reference potential electrode 39B includes a first potential connection portion 36A and a second potential connection portion 36B, as in the first modification. In addition, the reference potential electrode 39B also includes three third potential connection portions. The three third potential connection portions are, specifically, a third potential connection portion 36C, a third potential connection portion 36D, and a third potential connection portion 36E.

The three third potential connection portions are located between two of the plurality of third electrode fingers 27, of the reference potential electrode 39B, at both ends in the electrode finger orthogonal direction. More specifically, the third potential connection portion 36C is located at the connection electrode 34 that connects the leading ends of the adjacent third electrode fingers 27 on the second busbar 33 side. On the other hand, the third potential connection portion 36D and the third potential connection portion 36E are each located at the connection electrode 34 that connect the leading ends of the adjacent third electrode fingers 27 on the first busbar 32 side. The third potential connection portion 36C is located between the third potential connection portion 36D and the third potential connection portion 36E.

The connection wiring connected to the third potential connection portion 36C passes between the split busbar portion 33A and the split busbar portion 33B of the second busbar 33. The connection wiring connected to the third potential connection portion 36D passes between the split busbar portion 32A and the split busbar portion 32B of the first busbar 32. The connection wiring connected to the third potential connection portion 36E passes between the split busbar portion 32B and the split busbar portion 32C of the first busbar 32.

In the present modification, the reference potential electrode 39B includes five potential connection portions. This makes it possible to effectively shorten the length of the portion between the potential connection portions. This can effectively lower the electric resistance of the reference potential electrode 39B.

In addition, it is possible also in the present modification, as in the first example embodiment and the first modification, to achieve miniaturization of a filter device and to reduce the insertion loss when the acoustic wave device is used in the filter device. The number and positions of the potential connection portions are not limited to the above. The numbers of divisions of the first busbar 32 and the second busbar 33 are also not limited to the above. At least one of the first busbar 32 and the second busbar 33 may be divided.

A configuration of the second example embodiment will be described below. The basic configuration of the second example embodiment is the same or substantially the same as that of the first example embodiment. Therefore, in the description of the second example embodiment, the drawings and reference numerals used in the description of the first example embodiment will be used. The second example embodiment differs from the first example embodiment in that the relationship between the intersection width Ap and the center-to-center distance px between the adjacent electrode fingers is limited to Ap/px≥about 5, for example.

The second example embodiment has the following configuration. 1) Third electrode fingers 27 of a reference potential electrode 19 are provided between first electrode fingers 25 of a first comb-shaped electrode 17 and second electrode fingers 26 of a second comb-shaped electrode 18. 2) Ap/px≥about 5. This makes it possible to achieve miniaturization of a filter device and to reduce the insertion loss when the acoustic wave device 10 is used in the filter device. In the second example embodiment, the total number of the plurality of electrode fingers and Euler angles of a piezoelectric layer 14 are not particularly limited. The above advantageous effects will be described below.

The insertion loss around 6 GHz is compared by changing Ap/px. The acoustic wave devices in this comparison also include an acoustic wave device in which Ap/px<about 5. Specifically, Ap/px is changed in the range of about 1.25 to about 12.5. The design parameters of the acoustic wave devices in this comparison are as follows.
Piezoelectric layer
Material: LiNbO₃
Euler angles (φ, θ, ψ): (0°, 0°, 90°)
Thickness: about 400 nm
First to third electrode fingers
Layer structure: Ti layer/AlCu layer/Ti layer from the piezoelectric layer side
Thickness of each layer: about 10 nm/about 390 nm/about 4 nm from the piezoelectric layer side

Order of the first to third electrode fingers expressed by the potential to be connected: IN, GND, OUT, and GND are repeated in this order.

Center-to-center distance px between adjacent electrode fingers: about 1.4 μm
Duty ratio of functional electrode: about 0.3
Ap/px: changed in the range of about 1.25 to about 12.5

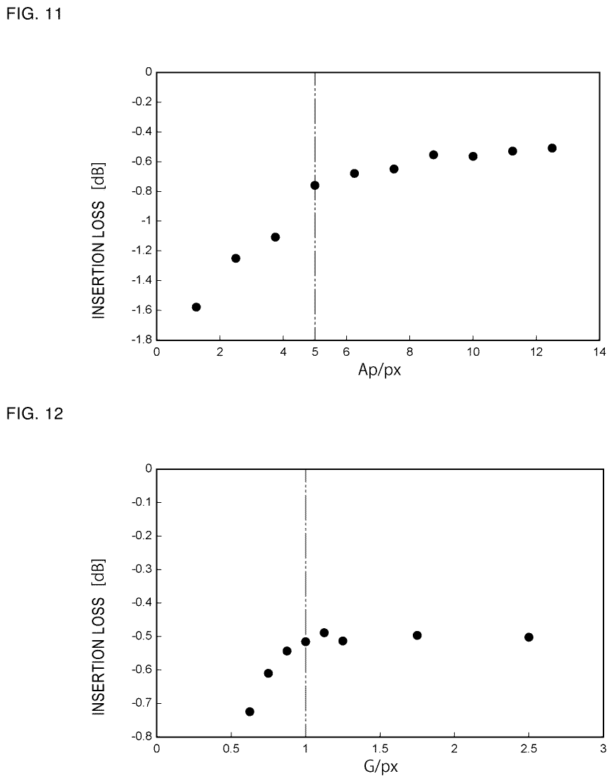

FIG. 11 is a graph illustrating a relationship between Ap/px and the insertion loss around 6 GHZ.

As can be seen from FIG. 11, the larger Ap/px, the smaller the insertion loss. It can also be seen that the slope of the change in insertion loss relative to the change in Ap/px is significantly different between when Ap/px<about 5 and when Ap/px≥about 5. Specifically, the slope when Ap/px<about 5 is larger than the slope when Ap/px≥about 5. When Ap/px<about 5, the insertion loss becomes much smaller as Ap/px approaches 5. When Ap/px≥about 5, as in the second example embodiment, the insertion loss can be effectively reduced.

In addition, in the second example embodiment, as in the first example embodiment, when the acoustic wave device 10 is used as an acoustic wave resonator in a filter device, a filter waveform can be suitably obtained even with one or a small number of acoustic wave resonators that constitute the filter device. This makes it possible to achieve miniaturization of the filter device.

The total number of the plurality of electrode fingers is, for example, preferably equal to or greater than sixteen also in the second example embodiment. This makes it possible to more reliably and effectively reduce the insertion loss. It is preferable that the Euler angles (φ, θ, ψ) of the piezoelectric layer 14 are within the range of Expression (1), Expression (2), or Expression (3) described above. This makes it possible to more reliably increase the value of the fractional band width.

Hereinafter, configurations of third and fourth example embodiments of the present invention will be described. The basic configuration of the third and fourth example embodiments is the same or substantially the same as that of the first example embodiment. Therefore, in the description of the third and fourth example embodiments, the drawings and reference numerals used in the description of the first example embodiment will be used. The third example embodiment differs from the first example embodiment in that the relationship between the gap length G and the center-to-center distance px between adjacent electrode fingers is limited to, for example, G/px≥about 1, and in the range of the Euler angles of the piezoelectric layer 14. The fourth example embodiment differs from the first example embodiment in that the relationship between the gap length G and the center-to-center distance px between adjacent electrode fingers is limited to G/px≤ about 0.5, for example.

In the third and fourth example embodiments, a gap length G of a gap g1 is the same or substantially the same as that of a gap g2. However, the gap length G of the gap g1 and the gap length G of the gap g2 may be different from each other.

The third example embodiment has the following configuration. 1) The Euler angles (φ, θ, ψ) of the piezoelectric layer 14 are (within the range of 0°±5°, within the range of −8°±14°, within the range of) 90°±5°. 2) Third electrode fingers 27 of a reference potential electrode 19 are provided between first electrode fingers 25 of a first comb-shaped electrode 17 and second electrode fingers 26 of a second comb-shaped electrode 18. 3) The relationship between the center-to-center distance px between adjacent electrode fingers and the gap length G is G/px≥ about 1, for example. This makes it possible to achieve miniaturization of a filter device and reduce insertion loss when the acoustic wave device 10 is used in the filter device. This will be described below. The total number of the plurality of electrode fingers is not particularly limited in the third example embodiment.

The insertion loss around 6 GHz is compared by changing G/px. The acoustic wave devices in this comparison also include an acoustic wave device in which about 0.5<G/px<about 1. Specifically, Ap/px is changed in the range of about 0.625 to about 2.5. The design parameters of the acoustic wave devices in this comparison are as follows.
Piezoelectric layer
Material: LiNbO₃
Euler angles (φ, θ, ψ): (0°, 0°, 90°)
Thickness: about 400 nm
First to third electrode fingers
Layer structure: Ti layer/AlCu layer/Ti layer from the piezoelectric layer side
Thickness of each layer: about 10 nm/about 390 nm/about 4 nm from the piezoelectric layer side

Order of the first to third electrode fingers expressed by the potential to be connected: IN, GND, OUT, and GND are repeated in this order.
Center-to-center distance px between adjacent electrode fingers: about 1.4 μm
Duty ratio of functional electrode: about 0.3
G/px: changed in the range of about 0.625 to about 2.5

FIG. 12 is a graph illustrating a relationship between G/px and the insertion loss around 6 GHZ.

As can be seen from FIG. 12, when about 0.5<G/px<about 1, the insertion loss becomes much smaller as G/px approaches 1. When G/px≥about 1, the insertion loss can be effectively reduced.

In addition, in the third example embodiment, as in the first example embodiment, when the acoustic wave device 10 is used as an acoustic wave resonator in a filter device, a filter waveform can be suitably obtained even with one or a small number of acoustic wave resonators that define the filter device. This makes it possible to achieve miniaturization of the filter device.

The total number of the plurality of electrode fingers is, for example, preferably equal to or greater than sixteen also in the third example embodiment. This makes it possible to more reliably and effectively reduce the insertion loss.

FIG. 12 illustrates the insertion loss when the Euler angles (φ, θ, ψ) of the piezoelectric layer 14 are (0°, 0°, 90°) in the third example embodiment. However, the Euler angles (φ, θ, ψ) of the piezoelectric layer 14 may be (within the range of 0°±5°, within the range of −8°±14°, within the range of 90°±5°). In this case, the insertion loss can be reduced by setting G/px≥about 1, for example.

The fourth example embodiment has the following configuration. 1) The Euler angles (φ, θ, ψ) of the piezoelectric layer 14 are within the range of Expression (1), Expression (2), or Expression (3) described above. 2) Third electrode fingers 27 of a reference potential electrode 19 are provided between first electrode fingers 25 of a first comb-shaped electrode 17 and second electrode fingers 26 of a second comb-shaped electrode 18. 3) The relationship between the center-to-center distance px between adjacent electrode fingers and the gap length G is G/px≤ about 0.5, for example. This makes it possible to achieve miniaturization of a filter device and reduce insertion loss when the acoustic wave device 10 is used in the filter device. This will be described below. Note that the total number of the plurality of electrode fingers is not particularly limited in the fourth example embodiment.

The insertion loss around 6 GHz is compared by changing G/px. The acoustic wave devices in this comparison also include an acoustic wave device in which about 0.5<G/px. Specifically, G/px is changed in the range of about 0.125 to about 1.25. The design parameters of the acoustic wave devices in this comparison are as follows.
Piezoelectric layer
Material: LiNbO₃
Euler angles (φ, θ, ψ): (0°, 127.5°, 0°)
Thickness: about 400 nm
First to third electrode fingers
Layer structure: Ti layer/AlCu layer/Ti layer from the piezoelectric layer side
Thickness of each layer: about 10 nm/about 390 nm/about 4 nm from the piezoelectric layer side
Order of the first to third electrode fingers expressed by the potential to be connected: IN, GND, OUT, and GND are repeated in this order.
Center-to-center distance px between adjacent electrode fingers: about 1.4 μm
Duty ratio of functional electrode: about 0.3 G/px: changed in the range of about 0.125 to 1.25

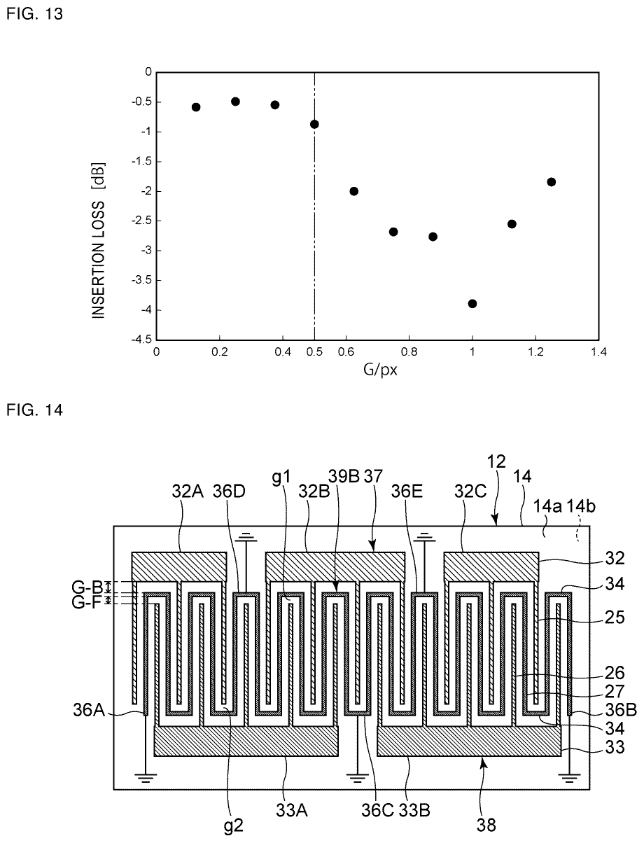

FIG. 13 is a graph illustrating a relationship between G/px and the insertion loss around 6 GHZ.

As can be seen from FIG. 13, for example, when about 0.5≤G/px, the insertion loss can be effectively reduced.

In addition, it is possible also in the fourth example embodiment, as in the first example embodiment, to achieve miniaturization of the filter device. The total number of the plurality of electrode fingers is, for example, preferably equal to or greater than sixteen also in the fourth example embodiment. This makes it possible to more reliably and effectively reduce the insertion loss.

FIG. 13 illustrates the insertion loss in the fourth example embodiment where the Euler angles (φ, θ, ψ) of the piezoelectric layer 14 are (0°, 127.5°, 0°). However, for example, when the piezoelectric layer 14 is made of rotated Y-cut lithium niobate, the insertion loss can be reduced by setting G/px≤ about 0.5. In addition, when the Euler angles (φ, θ, ψ) of the piezoelectric layer 14 are within the range of Expression (1), Expression (2), or Expression (3) described above, as in the present example embodiment, the value of the fractional band width can be more reliably increased.

In the second to fourth example embodiments, as illustrated with reference to FIG. 2, the connection electrode is the third busbar 24. The reference potential electrode 19 is a comb-shaped electrode. However, the reference potential electrode 39A illustrated in FIG. 9 or the reference potential electrode 39B illustrated in FIG. 10 may also be used in the second to fourth example embodiments. In the second to fourth example embodiments, the reference potential electrode may have a meandering shape.

Further examples of the reference potential electrode having a meandering shape will be described below in fifth and sixth example embodiments of the present invention.

FIG. 14 is a schematic plan view of an acoustic wave device according to the fifth example embodiment. In FIG. 14, reference numeral G-B denotes a G-B gap length to be described later and reference numeral G-F denotes a G-F gap length.

The present example embodiment differs from the first example embodiment in the configurations of the first busbar 32, the second busbar 33, and the reference potential electrode 39B. The basic configurations of the first busbar 32, the second busbar 33, and the reference potential electrode 39B are the same or substantially the same as those of the second modification of the first example embodiment. In the present example embodiment, however, the distance between a connection electrode 34 and the leading ends of electrode fingers and the busbar is limited. Otherwise, an acoustic wave device of the fifth example embodiment has the same or substantially the same configuration as that of the acoustic wave device 10 of the first example embodiment.

Hereinafter, the between the connection distance electrode 34 connecting the leading ends of adjacent third electrode fingers 27 on the first busbar 32 side and the first busbar 32 is the G-B gap length. The distance between the connection electrode 34 and the leading end of the second electrode finger 26 is the G-F gap length.

The present example embodiment has the following configuration. 1) The Euler angles (φ, θ, ψ) of the piezoelectric layer 14 are within the range of Expression (1), Expression (2), or Expression (3) described above. 2) The third electrode fingers 27 of the reference potential electrode 19 are provided between the first electrode fingers 25 of the first comb-shaped electrode 17 and the second electrode fingers 26 of the second comb-shaped electrode 18. 3) G-B gap length≤G-F gap length. This makes it possible to achieve miniaturization of a filter device and reduce insertion loss when the acoustic wave device is used in the filter device.

In the present example embodiment, the total number of the first electrode fingers 25, the second electrode fingers 26, and the third electrode fingers 27 is not particularly limited. However, it is preferable that the total number of the first electrode fingers 25, the second electrode fingers 26, and the third electrode fingers 27 is, for example, equal to or greater than sixteen. This makes it possible to more reliably and effectively reduce the insertion loss.

In the present example embodiment, the first comb-shaped electrode 37 is connected to the input potential. The second comb-shaped electrode 38 is connected to the output potential. Therefore, the G-B gap length is the distance between the connection electrode 34 connected to the reference potential and the first busbar 32 connected to the input potential. The G-F gap length is the distance between the connection electrode 34 connected to the reference potential and the leading end of the second electrode finger 26 connected to the output potential.

However, the first comb-shaped electrode 37 may be connected to the output potential and the second comb-shaped electrode 38 may be connected to the input potential. In this case, the G-B gap length is the distance between the connection electrode 34 connected to the reference potential and the first busbar 32 connected to the output potential. The G-F gap length is the distance between the connection electrode 34 connected to the reference potential and the leading end of the second electrode finger 26 connected to the input potential.

Alternatively, the G-B gap length may be the distance between the connection electrode 34, which connects the leading ends of the adjacent third electrode fingers 27 on the second busbar 33 side, and the second busbar 33. In this case, the G-F gap length is the distance between the connection electrode 34 and the leading end of the first electrode finger 25.

A configuration of the sixth example embodiment will be described below. The configuration of the sixth example embodiment is basically the same as that of the fifth example embodiment. Therefore, in the description of the sixth example embodiment, the drawings and reference numerals used in the description of the fifth example embodiment will be used. The sixth example embodiment differs from the fifth example embodiment in that G-B gap length>G-F gap length and in the range of the Euler angles of the piezoelectric layer 14.

The sixth example embodiment has following configuration. 1) The Euler angles (φ, θ, ψ) of the piezoelectric layer 14 are (within the range of 0°±5°, within the range of −8°±14°, within the range of) 90°±5°. 2) Third electrode fingers 27 of a reference potential electrode 19 are provided between first electrode fingers 25 of a first comb-shaped electrode 17 and second electrode fingers 26 of a second comb-shaped electrode 18. 3) G-B gap length>G-F gap length. This makes it possible to achieve miniaturization of a filter device and reduce insertion loss when the acoustic wave device is used in the filter device.

In the sixth example embodiment, the total number of the first electrode fingers 25, the second electrode fingers 26, and the third electrode fingers 27 is not particularly limited. However, for example, it is preferable that the total number of the first electrode fingers 25, the second electrode fingers 26, and the third electrode fingers 27 is equal to or greater than sixteen. This makes it possible to more reliably and effectively reduce the insertion loss.

The fifth and sixth example embodiments illustrate the examples where the G-B gap length and the G-F gap length are defined when the reference potential electrode has a meandering shape. The G-B gap length and the G-F gap length can also be defined for the reference potential electrode 19, which is a comb-shaped electrode, as illustrated in FIG. 2. Specifically, the G-B gap length is the distance between the third busbar 24 and the first busbar 22. The G-F gap length corresponds to the gap length G in the gap g1.

Even when the reference potential electrode 19 is a comb-shaped electrode, the G-B gap length may be less than or equal to the G-F gap length, as in the fifth example embodiment. Alternatively, the G-B gap length may be greater than the G-F gap length, as in the sixth example embodiment.

The thickness-shear mode will be described in detail below using an example where the functional electrode is an IDT electrode. The IDT electrode includes no third electrode fingers. The “electrode” in the IDT electrode described below corresponds to the electrode finger. A support in the following example corresponds to the support substrate. The reference potential may be hereinafter referred to as a ground potential.

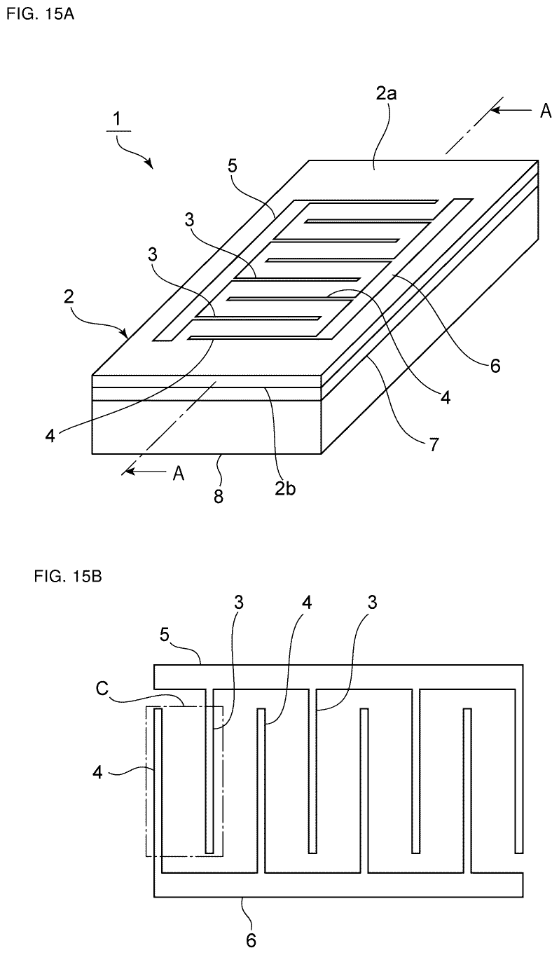

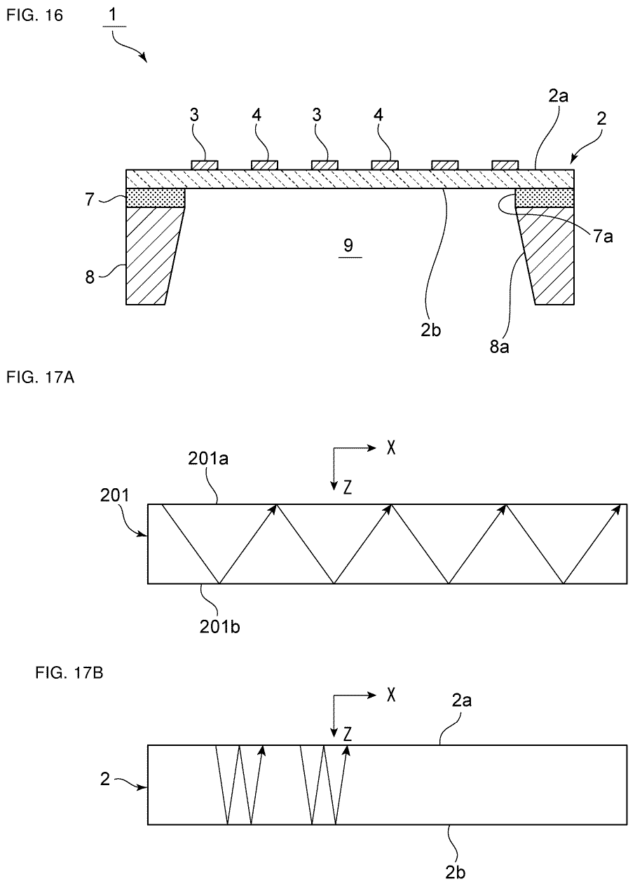

FIG. 15A is a schematic perspective view illustrating an appearance of an acoustic wave device that uses a thickness-shear mode bulk wave. FIG. 15 is a plan view illustrating an electrode structure on a piezoelectric layer. FIG. 16 is a cross-sectional view of a portion taken along line A-A in FIG. 15A.

An acoustic wave device 1 according to an example embodiment of the present invention includes a piezoelectric layer 2 made of, for example, LiNbO₃. The piezoelectric layer 2 may be made of, for example, LiTaO₃. The cut-angle of LiNbO₃ or LiTaO₃ is a Z-cut in the present example embodiment, but may be a rotated Y-cut or X-cut. The thickness of the piezoelectric layer 2 is not particularly limited, but is, for example, preferably equal to or greater than about 40 nm and less than or equal to about 1000 nm, and more preferably equal to or greater than about 50 nm and less than or equal to about 1000 nm in order to effectively excite a thickness-shear mode. The piezoelectric layer 2 includes a first main surface 2a and a second main surface 2b facing each other. An electrode 3 and an electrode 4 are provided on the first main surface 2a. Here, the electrode 3 is an example of a “first electrode” and the electrode 4 is an example of a “second electrode”. In FIGS. 15A and 15B, a plurality of the electrodes 3 are connected to a first busbar 5. A plurality of the electrodes 4 are connected to a second busbar 6. The plurality of electrodes 3 and the plurality of electrodes 4 are interdigitated with each other. The electrode 3 and the electrode 4 have a rectangular or substantially rectangular shape and have a length direction. In a direction orthogonal or substantially orthogonal to the length direction, the electrode 3 and the electrode 4 adjacent thereto face each other. The length direction of the electrodes 3 and 4 and the direction orthogonal or substantially orthogonal to the length direction of the electrodes 3 and 4 each are a direction intersecting a thickness direction of the piezoelectric layer 2. Therefore, it can also be said that the electrode 3 and the electrode 4 adjacent thereto face each other in the direction intersecting the thickness direction of the piezoelectric layer 2. The length direction of the electrodes 3 and 4 may be replaced with the direction orthogonal or substantially orthogonal to the length direction of the electrodes 3 and 4 illustrated in FIGS. 15A and 15B. That is, the electrodes 3 and 4 may extend in the direction in which the first busbar 5 and the second busbar 6 extend in FIGS. 15A and 15B. In this case, the first busbar 5 and the second busbar 6 extend in the direction in which the electrodes 3 and 4 extend in FIGS. 15A and 15B. A plurality of pairs of structures in which the electrode 3 connected to one potential and the electrode 4 connected to the other potential are adjacent to each other are provided in the direction orthogonal or substantially orthogonal to the length direction of the electrodes 3 and 4 described above. Here, the electrode 3 and the electrode 4 being adjacent to each other refers not to a case where the electrode 3 and the electrode 4 are arranged so as to be in direct contact with each other but to a case where the electrode 3 and the electrode 4 are arranged with an interval therebetween. When the electrode 3 and the electrode 4 are adjacent to each other, an electrode connected to a hot electrode or a ground electrode, including the other electrodes 3 and 4, is not arranged between the electrode 3 and the electrode 4. The number of pairs need not be integer pairs, but may be, for example, 1.5 pairs, 2.5 pairs, or the like. The center-to-center distance between the electrodes 3 and 4, that is, the pitch is, for example, preferably in the range of equal to or greater than about 1 μm and less than or equal to about 10 μm. In addition, the width of the electrodes 3 and 4, that is, the dimension of the electrodes 3 and 4 in their facing direction, is, for example, preferably in the range of equal to or greater than about 50 nm and less than or equal to about 1000 nm, and more preferably in the range of equal to or greater than about 150 nm and less than or equal to about 1000 nm. The center-to-center distance between the electrodes 3 and 4 is a distance connecting the center of the dimension (width dimension) of the electrode 3 orthogonal in the direction or substantially orthogonal to the length direction of the electrode 3 and the center of the dimension (width dimension) of the electrode 4 in the direction orthogonal or substantially orthogonal to the length direction of the electrode 4.

In the acoustic wave device 1, since the Z-cut piezoelectric layer is used, the direction orthogonal or substantially orthogonal to the length direction of the electrodes 3 and 4 is a direction orthogonal or substantially orthogonal to the polarization direction of the piezoelectric layer 2. This does not apply when a piezoelectric body of another cut-angle is used as the piezoelectric layer 2. Here, the term “orthogonal” is not limited to strictly orthogonal but may be substantially orthogonal (an angle between the direction orthogonal to the length direction of the electrodes 3 and 4 and the polarization direction is, for example, about 90°±) 10°.

A support 8 is laminated on the second main surface 2b side of the piezoelectric layer 2 with an insulating layer 7 interposed therebetween. The insulating layer 7 and the support 8 have a frame shape and include through-holes 7a and 8a as illustrated in FIG. 16. A cavity 9 is thus provided. The cavity 9 is provided so as not to interfere with the vibration of an excitation region C of the piezoelectric layer 2. Therefore, the support 8 is laminated on the second main surface 2b with the insulating layer 7 interposed therebetween at a position not overlapping with a portion where at least a pair of electrodes 3 and 4 are provided. The insulating layer 7 need not be provided. Therefore, the support 8 can be directly or indirectly laminated on the second main surface 2b of the piezoelectric layer 2.

The insulating layer 7 is made of, for example, silicon oxide. However, the insulating layer 7 can be made of an appropriate insulating material such as, for example, silicon oxynitride or alumina in addition to silicon oxide. The support 8 is made of, for example, Si. The plane orientation of the surface of Si on the piezoelectric layer 2 side may be (100), (110), or (111). Preferably, for example, high-resistance Si of the support 8 with a resistivity of equal to or greater than about 4 kΩ cm is provided. However, the support 8 can also be made using an appropriate insulating material or semiconductor material.

Examples of the material of the support 8 include piezoelectric bodies such as aluminum oxide, lithium tantalate, lithium niobate, or quartz crystal, various ceramics such as alumina, magnesia, sapphire, silicon nitride, aluminum nitride, silicon carbide, zirconia, cordierite, mullite, steatite, or forsterite, dielectrics such as diamond or glass, semiconductors such as gallium nitride, or the like.

The plurality of electrodes 3 and 4 and the first and second busbars 5 and 6 are made of an appropriate metal or alloy such as, for example, Al or an AlCu alloy. In the acoustic wave device 1, the electrodes 3 and 4 and the first and second busbars 5 and 6 have, for example, a structure in which an Al film is laminated on a Ti film. A close contact layer other than the Ti film may be used.

At the time of driving, an AC voltage is applied between the plurality of electrodes 3 and the plurality of electrodes 4. More specifically, an AC voltage is applied between the first busbar 5 and the second busbar 6. This makes it possible to obtain resonance characteristics using a bulk wave in the thickness-shear mode excited in the piezoelectric layer 2. In the acoustic wave device 1, for example, d/p is less than or equal to about 0.5, where d is the thickness of the piezoelectric layer 2, and p is the center-to-center distance between any adjacent electrodes 3 and 4 of the plurality of pairs of electrodes 3 and 4. Therefore, the bulk wave in the thickness-shear mode is effectively excited, and good resonance characteristics can be obtained. More preferably, for example, d/p is less than or equal to about 0.24, in which case even better resonance characteristics can be obtained.

Since the acoustic wave device 1 has the configuration described above, even when the number of pairs of the electrodes 3 and 4 is reduced in an attempt for miniaturization, Q value is not easily reduced. This is because the propagation loss is small even if the number of electrode fingers in the reflectors on both sides is reduced. In addition, the reason why the number of electrode fingers can be reduced is that the bulk wave in the thickness-shear mode is used. The difference between a Lamb wave used in an acoustic wave device and the thickness-shear mode bulk wave described above will be described with reference to FIGS. 17A and 17B.

FIG. 17A is a schematic elevational cross-sectional view for explaining a Lamb wave propagating through a piezoelectric film of an acoustic wave device as described in Japanese Unexamined Patent Application Publication No. 2012-257019. As illustrated in FIG. 17A, a wave propagates through a piezoelectric film 201 as indicated by arrows. Here, the piezoelectric film 201 includes a first main surface 201a and a second main surface 201b, which face each other, and a thickness direction connecting the first main surface 201a and the second main surface 201b is the Z direction. The X direction is a direction in which electrode fingers of an IDT electrode are arranged. As illustrated in FIG. 17A, the Lamb wave propagates in the X direction. Although the piezoelectric film 201 vibrates as a whole because of the plate wave, since the wave propagates in the X direction, reflectors are arranged on both sides to obtain resonance characteristics. Therefore, a propagation loss of waves occurs, and the Q value decreases when the size is reduced, that is, when the number of pairs of electrode fingers is reduced.

On the other hand, as illustrated in FIG. 17B, in the acoustic wave device 1, since the vibration displacement is in the thickness-shear direction, the wave substantially propagates in the direction connecting the first main surface 2a and the second main surface 2b of the piezoelectric layer 2, that is, the Z direction, and resonates. Specifically, the X direction component of the wave is significantly smaller than the Z direction component. Since resonance characteristics are obtained by the propagation of the wave in the Z direction, propagation loss does not easily occur even when the number of electrode fingers of the reflector is reduced. Furthermore, even when the number of pairs of electrodes of the electrodes 3 and 4 is reduced in an attempt to promote miniaturization, the Q value is not easily reduced.

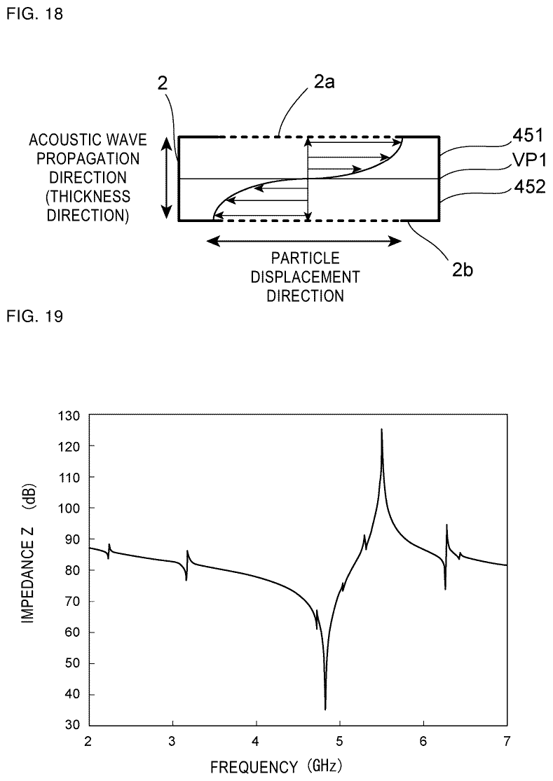

As illustrated in FIG. 18, the amplitude direction of the bulk wave in the thickness-shear mode in a first region 451 included in the excitation region C of the piezoelectric layer 2 is the opposite in a second region 452 included in the excitation region C. FIG. 18 schematically illustrates a bulk wave when a voltage is applied between the electrode 3 and the electrode 4 so that the electrode 4 has a higher potential than the electrode 3. The first region 451 is a region between the first main surface 2a and a virtual plane VP1 that is orthogonal or substantially orthogonal to the thickness direction of the piezoelectric layer 2 and divides the piezoelectric layer 2 into two portions in the excitation region C. The second region 452 is a region between the virtual plane VP1 and the second main surface 2b in the excitation region C.

As described above, in the acoustic wave device 1, at least a pair of electrodes including the electrode 3 and the electrode 4 are provided. However, since waves are not propagated in the X direction, the plurality of pairs of electrodes including the electrodes 3 and 4 are not always necessary. That is, only at least a pair of electrodes may be provided.

For example, the electrode 3 is an electrode connected to the hot potential, and the electrode 4 is an electrode connected to the ground potential. However, the electrode 3 may be connected to the ground potential and the electrode 4 may be connected to the hot potential. In the acoustic wave device 1, as described above, at least a pair of electrodes are the electrode connected to the hot potential or the electrode connected to the ground potential, and a floating electrode is not provided.

FIG. 19 is a graph illustrating resonance characteristics of the acoustic wave device illustrated in FIG. 16. The design parameters of the acoustic wave device 1 having the resonance characteristics are as follows.
Piezoelectric layer 2: LiNbO₃ with Euler angles (0°, 0°) 90°
Thickness: about 400 nm
Length of region where electrodes 3 and 4 overlap as seen in direction orthogonal or substantially orthogonal to length direction of electrodes 3 and 4, that is, excitation region C: about 40 μm
Number of pairs of electrodes consisting of electrodes 3 and 4: 21 pairs
Center-to-center distance between electrodes: about 3 μm
Width of electrodes 3 and 4: about 500 nm
d/p: about 0.133
Insulating layer 7: silicon oxide film with thickness of about 1 μm
Support 8: Si

The length of the excitation region C is a dimension of the excitation region C along the length direction of the electrodes 3 and 4.

In the acoustic wave device 1, the electrode-to-electrode distances of the electrode pairs including the electrodes 3 and 4 are all equal or substantially equal in the plurality of pairs. That is, the electrodes 3 and the electrodes 4 are arranged with equal or substantially equal pitches.

As is clear from FIG. 19, good resonance characteristics with the fractional band width of about 12.5% are obtained even though no reflector is provided.

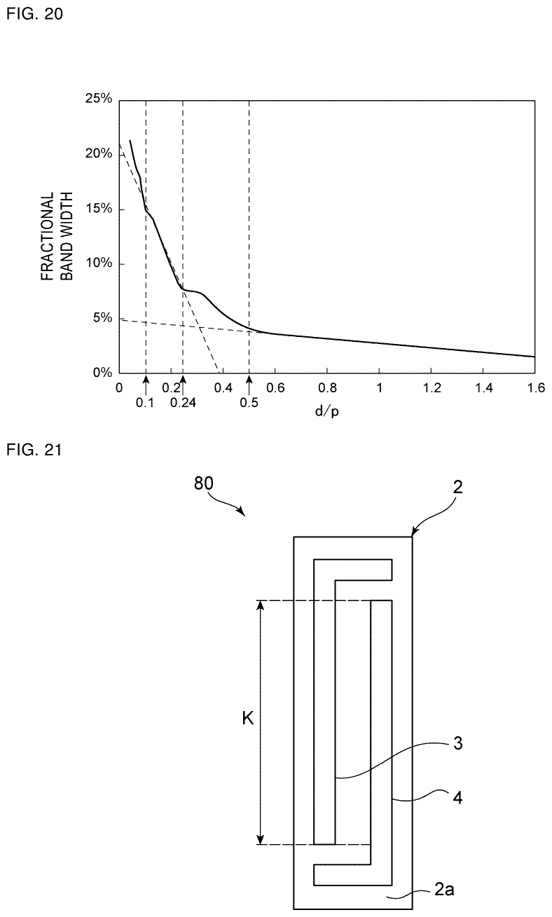

As described above, in the acoustic wave device 1, d/p is, for example, less than or equal to about 0.5, and more preferably less than or equal to about 0.24, where d is the thickness of the piezoelectric layer 2 and p is the center-to-center distance between the electrode 3 and the electrode 4. This will be described with reference to FIG. 20.

A plurality of acoustic wave devices are obtained in the same or substantially the same manner as the acoustic wave device having the resonance characteristics illustrated in FIG. 19, except that d/p is changed. FIG. 20 is a graph illustrating a relationship between d/p and the fractional band width of the acoustic wave device as a resonator.

As is clear from FIG. 20, when d/p>about 0.5, the fractional band width is less than about 5% even if d/p is adjusted. On the other hand, when d/p≥about 0.5, the fractional band width can be set to equal to or greater than about 5% by changing d/p within that range, that is, a resonator with a high coupling coefficient can be configured. Furthermore, when d/p is less than or equal to about 0.24, the fractional band width can be increased to equal to or greater than about 7%. In addition, by adjusting d/p within this range, a resonator with an even wider fractional band width can be obtained, and a resonator with an even higher coupling coefficient can be realized. Therefore, it can be seen that, by setting d/p to less than or equal to about 0.5, a resonator with a high coupling coefficient can be configured using the thickness-shear mode bulk wave.

FIG. 21 is a plan view of an acoustic wave device that uses a thickness-shear mode bulk wave. In an acoustic wave device 80, a pair of electrodes, including an electrode 3 and an electrode 4, are provided on a first main surface 2a of a piezoelectric layer 2. K in FIG. 21 is an intersection width. As described above, in an acoustic wave device according to an example embodiment of the present invention, the number of pairs of electrodes may be one. Even in this case, for example, when the d/p is less than or equal to about 0.5, the thickness-shear mode bulk wave can be effectively excited.

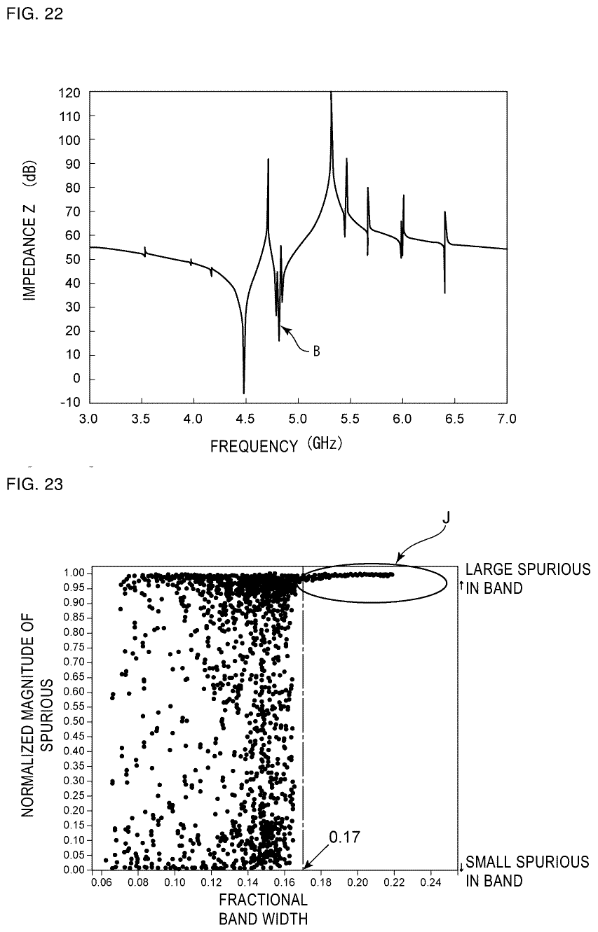

In the acoustic wave device 1, for example, it is preferable that a metallization ratio MR of any adjacent electrodes 3 and 4 of the plurality of electrodes 3 and 4 with respect to the excitation region C, which is a region where the adjacent electrodes 3 and 4 overlap when viewed in their facing direction, satisfies MR≤about 1.75 (d/p)+0.075. In that case, spurious can be effectively reduced. This will be described with reference to FIGS. 22 and 23. FIG. 22 is a reference diagram illustrating an example of the resonance characteristics of the acoustic wave device 1. A spurious response indicated by an arrow B appears between a resonant frequency and an anti-resonant frequency. d/p=about 0.08 and the Euler angles of LiNbO₃ are (0°, 0°, 90°). The metallization ratio MR is about 0.35.

The metallization ratio MR will be described with reference to FIG. 15B. In the electrode structure of FIG. 15B, when focusing on a pair of electrodes 3 and 4, it is assumed that only this pair of electrodes 3 and 4 is provided. In this case, a portion surrounded by a dashed-dotted line is the excitation region C. When the electrode 3 and the electrode 4 are viewed in the direction orthogonal or substantially orthogonal to the length direction of the electrodes 3 and 4, that is, in their facing direction, the excitation region C is a region of the electrode 3 that overlaps the electrode 4, a region of the electrode 4 that overlaps the electrode 3, and a region between the electrode 3 and the electrode 4 where the electrode 3 and the electrode 4 overlap each other. An area of the electrodes 3 and 4 in the excitation region C with respect to the area of the excitation region C is the metallization ratio MR. That is, the metallization ratio MR is the ratio of the area of the metallization portion to the area of the excitation region C.

When a plurality of pairs of electrodes are provided, the ratio of the metallization portion included in the entire excitation region to the total area of the excitation region may be MR.

FIG. 23 is a diagram illustrating a relationship between a fractional band width and a phase rotation amount of the spurious impedance normalized by about 180 degrees as the magnitude of the spurious when a large number of acoustic wave resonators are configured according to the configuration of the acoustic wave device 1. The fractional band width is adjusted by changing the film thickness of the piezoelectric layer and the dimensions of the electrodes. FIG. 23 illustrates the results when a Z-cut LiNbO₃ piezoelectric layer is used, but the same tendency is obtained also when piezoelectric layers with other cut-angles are used.

In a region surrounded by an ellipse J in FIG. 23, the spurious response is as large as about 1.0, for example. As is clear from FIG. 23, when the fractional band width exceeds about 0.17, that is, exceeds about 178, for example, a large spurious response with a spurious level of equal to or greater than about 1 appears in a pass band even when the parameters defining the fractional band width are changed. That is, as in the resonance characteristics illustrated in FIG. 22, a large spurious response indicated by the arrow B appears within the band. Therefore, the fractional band width is, for example, preferably less than or equal to about 17%. In this case, the spurious response can be reduced by adjusting the film thickness of the piezoelectric layer 2, the dimensions of the electrodes 3 and 4, or the like.

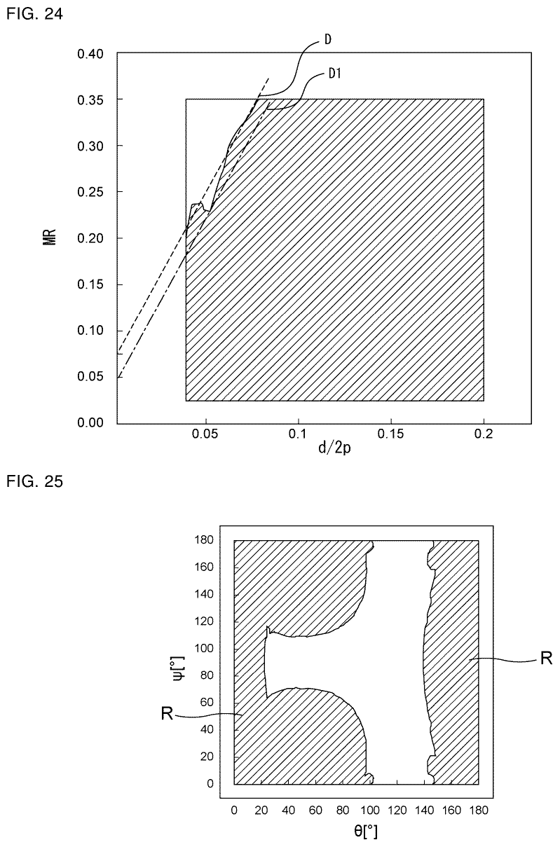

FIG. 24 is a diagram illustrating a relationship among d/2p, the metallization ratio MR, and the fractional band width. In the acoustic wave device, various acoustic wave devices having different values of d/2p and different values of MR are provided, and the fractional band width is measured. A hatched portion to the right of a dashed line D illustrated in FIG. 24 is a region where the fractional band width is less than or equal to about 17%, for example. The boundary between the hatched region and the non-hatched region is represented by MR=about 3.5 (d/2p)+0.075, for example. That is, MR=about 1.75 (d/p)+0.075. Therefore, for example, MR≤about 1.75 (d/p)+0.075 is preferably satisfied. In this case, the fractional band width is easily set to less than or equal to about 17%, for example. More preferably, for example, it is the region in FIG. 24 to the right of a dashed-dotted line D1 indicating MR=about 3.5 (d/2p)+0.05, for example. That is, when MR≤about 1.75 (d/p)+0.05, for example, the fractional band width can be reliably set to less than or equal to about 17%.

FIG. 25 is a diagram illustrating a map of the fractional band width with respect to the Euler angles (0°, θ, ψ) of LiNbO₃ when d/p is infinitely close to 0. A plurality of hatched regions R illustrated in FIG. 25 are regions where the fractional band width of equal to or greater than about 2% is obtained, for example. When φ in the Euler angles (φ, θ, ψ) is within the range of about 0°±5°, for example, the relationship between θ and ψ and the fractional band width is the same as that illustrated in FIG. 25. Also, for example, when the piezoelectric layer is made of lithium tantalate (LiTaO₃), the relationship between θ and ψ in the Euler angles (within the range of 0°±5°, θ, ψ) and BW is the same or substantially the same as that illustrated in FIG. 25.

Therefore, when φ in the Euler angles (φ, θ, ψ) of the lithium niobate or lithium tantalate of the piezoelectric layer is within the range of about 0°±5° and θ and φ are within the range of any of the regions R illustrated in FIG. 25, for example, the fractional band width can be sufficiently widened, which is preferable.

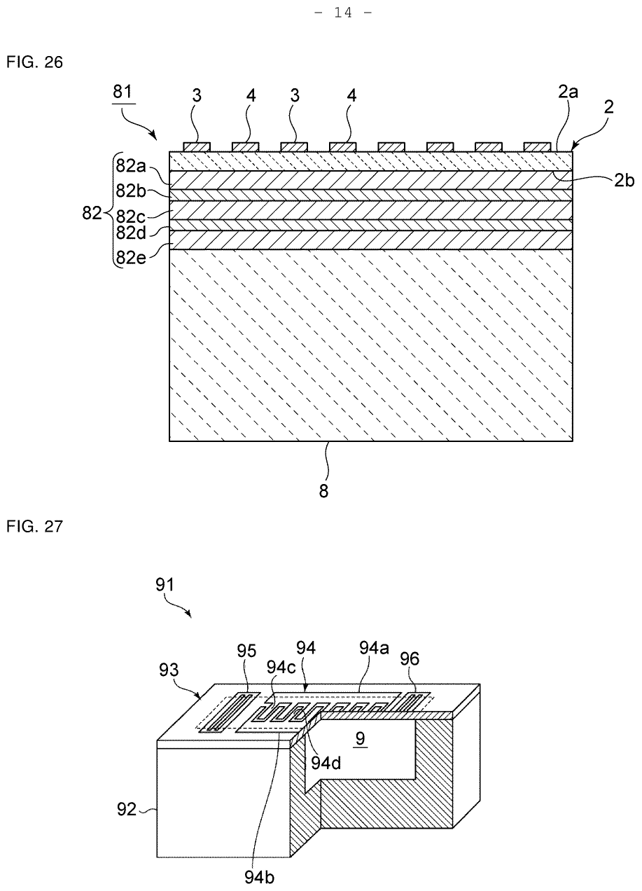

FIG. 26 is an elevational cross-sectional view of an acoustic wave device according to an example embodiment of the present invention including an acoustic multilayer film.

In an acoustic wave device 81, an acoustic multilayer film 82 is laminated on a second main surface 2b of a piezoelectric layer 2. The acoustic multilayer film 82 has a multilayer structure including low acoustic impedance layers 82a, 82c, and 82e with a relatively low acoustic impedance and high acoustic impedance layers 82b and 82d with a relatively high acoustic impedance. Using the acoustic multilayer film 82 makes it possible to confine the thickness-shear mode bulk wave in the piezoelectric layer 2 without using the cavity 9 in the acoustic wave device 1. In the acoustic wave device 81, resonance characteristics based on the thickness-shear mode bulk wave can be obtained by setting the above d/p to less than or equal to about 0.5, for example. In the acoustic multilayer film 82, the number of the low acoustic impedance layers 82a, 82c, and 82e and high acoustic impedance layers 82b and 82d laminated is not particularly limited. It is sufficient that at least one high acoustic impedance layer 82b or 82d is disposed farther from the piezoelectric layer 2 than the low acoustic impedance layers 82a, 82c, and 82e.

The low acoustic impedance layers 82a, 82c, and 82e and the high acoustic impedance layers 82b and 82d can be made of any appropriate material as long as the above acoustic impedance relationship is satisfied. Examples of the material of the low acoustic impedance layers 82a, 82c, and 82e include silicon oxide or silicon oxynitride, and the like. Alumina, silicon nitride, metal or the like can be used as the material of the high acoustic impedance layers 82b and 82d.

FIG. 27 is a partially cutaway perspective view for explaining an acoustic wave device that uses a Lamb wave.

An acoustic wave device 91 includes a support substrate 92. The support substrate 92 is provided with a recessed portion that is open on its upper surface. A piezoelectric layer 93 is laminated on the support substrate 92. A cavity 9 is thus provided. An IDT electrode 94 is provided on the piezoelectric layer 93 above the cavity 9. On both sides of the IDT electrode 94 in the acoustic wave propagation direction, reflectors 95 and 96 are provided. In FIG. 27, an outer periphery of the cavity 9 is indicated by a dashed line. Here, the IDT electrode 94 includes first and second busbars 94a and 94b, a plurality of first electrode fingers 94c, and a plurality of second electrode fingers 94d. The plurality of first electrode fingers 94c are connected to the first busbar 94a. The plurality of second electrode fingers 94d are connected to the second busbar 94b. The plurality of first electrode fingers 94c and the plurality of second electrode fingers 94d are interdigitated with each other.

In the acoustic wave device 91, a Lamb wave as a plate wave is excited by applying an AC electric field to the IDT electrode 94 above the cavity 9. Since the reflectors 95 and 96 are provided on both sides, resonance characteristics due to the Lamb wave can be obtained.

As described above, an acoustic wave device according to an example embodiment of the present invention may use a plate wave. In the example illustrated in FIG. 27, the IDT electrode 94, the reflector 95, and the reflector 96 are provided on the main surface corresponding to the first main surface 14a of the piezoelectric layer 14 illustrated in FIG. 1 and the like. In an acoustic wave device according to an example embodiment of the present invention, on the other hand, a pair of comb-shaped electrodes and a plurality of third electrode fingers are provided on the first main surface 14a. When an acoustic wave device according to an example embodiment of the present invention uses a plate wave, a pair of comb-shaped electrodes and a plurality of third electrode fingers as well as the reflector 95 and the reflector 96 may be provided on the first main surface 14a of the piezoelectric layer 14 in the first to sixth example embodiments and the respective modifications. In this case, the pair of comb-shaped electrodes and the plurality of third electrode fingers may be sandwiched between the reflector 95 and the reflector 96 in the electrode finger orthogonal direction.

In the acoustic wave devices of the first to sixth example embodiments and modifications, for example, the acoustic multilayer film 82 illustrated in FIG. 26 may be provided as an acoustic reflection film between the support and the piezoelectric layer. Specifically, the support and the piezoelectric layer may be arranged such that at least a portion of the support and at least a portion of the piezoelectric layer face each other across the acoustic multilayer film 82. In this case, it is sufficient that low acoustic impedance layers and high acoustic impedance layers are alternately laminated in the acoustic multilayer film 82. The acoustic multilayer film 82 may be an acoustic reflection portion in the acoustic wave device.

In the acoustic wave devices according to the first to sixth example embodiments and modifications that use the thickness-shear mode bulk wave, as described above, for example, d/p is preferably less than or equal to about 0.5, and more preferably less than or equal to about 0.24. This makes it possible to obtain even better resonance characteristics.

Furthermore, in the excitation region of the acoustic wave devices according to the first to sixth example embodiments and modifications that use the thickness-shear mode bulk wave, as described above, MR≤about 1.75 (d/p)+0.075, for example, is preferably satisfied. More specifically, MR≤about 1.75 (d/p)+0.075 is preferably satisfied, where MR is the metallization ratio of the first and third electrode fingers and the second and third electrode fingers to the excitation region. In this case, a spurious response can be more reliably reduced or prevented.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer made of lithium niobate with Euler angles (φ, θ, ψ) within a range of Expression (1), Expression (2), or Expression (3):
(within a range of 0°±10°, 0° to 25°, any ψ) Expression (1);
(within a range of 0°±10°, 25° to 100°, 0° to 75° [(1-(θ-50)²/2500)]^{1/2} or 180°-75° [(1−(θ-50)²/2500)]^{1/2} to 180°) Expression (2); and
(within a range of 0°±10°, 180°-40° [(1−(ψ-90)²/8100)]^{1/2} to 180°, any ψ) Expression (3);
a first comb-shaped electrode on the piezoelectric layer, including a first busbar and a plurality of first electrode fingers each including one end connected to the first busbar, and being connected to an input potential;
a second comb-shaped electrode on the piezoelectric layer, including a second busbar and a plurality of second electrode fingers each including one end connected to the second busbar and being interdigitated with the plurality of first electrode fingers, and being connected to an output potential; and
a reference potential electrode connected to a reference potential and including a plurality of third electrode fingers on the piezoelectric layer and aligned with the first electrode fingers and the second electrode fingers in a direction in which the first electrode fingers and the second electrode fingers are arranged, and a connection electrode connecting adjacent third electrode fingers; wherein
an order in which a first electrode finger, a second electrode finger, and a third electrode finger are arranged is such that, starting from the first electrode finger, the first electrode finger, the third electrode finger, the second electrode finger, and the third electrode finger define one period; and
a total number of the first electrode fingers, the second electrode fingers, and the third electrode fingers is equal to or greater than sixteen.

2. The acoustic wave device according to claim 1, wherein the acoustic wave device is structured to excite a plate wave.

3. The acoustic wave device according to claim 1, wherein the acoustic wave device is structured to excite a thickness-shear mode bulk wave.

4. The acoustic wave device according to claim 1, further comprising:
a support laminated on the piezoelectric layer; wherein
an acoustic reflection portion is provided at a position on the support overlapping with the plurality of first electrode fingers, the plurality of second electrode fingers, and the plurality of third electrode fingers in plan view along a lamination direction of the support and the piezoelectric layer; and
d/p is less than or equal to about 0.5, where p is a longest distance of a center-to-center distance between adjacent first and third electrode fingers and a center-to-center distance between adjacent second and third electrode fingers, and d is a thickness of the piezoelectric layer.

5. The acoustic wave device according to claim 4, wherein d/p is less than or equal to about 0.24.

6. The acoustic wave device according to claim 4, wherein
an excitation region is a region where the adjacent first and third electrode fingers overlap each other in an electrode finger orthogonal direction that is a direction orthogonal or substantially orthogonal to a direction in which the first electrode fingers, the second electrode fingers, and the third electrode fingers extend, and a region between centers of the adjacent first and third electrode fingers, and a region where the adjacent second and third electrode fingers overlap each other in the electrode finger orthogonal direction and a region between centers of the adjacent second and third electrode fingers; and
MR≤about 1.75 (d/p)+0.075 is satisfied, where MR is a metallization ratio of the first electrode fingers and the third electrode fingers, and the second electrode fingers and the third electrode fingers to the excitation region.

7. The acoustic wave device according to claim 4, wherein
the acoustic reflection portion is a cavity; and
a portion of the support and a portion of the piezoelectric layer face each other across the cavity.

8. The acoustic wave device according to claim 4, wherein
the acoustic reflection portion is an acoustic reflection film including a high acoustic impedance layer with a relatively high acoustic impedance and a low acoustic impedance layer with a relatively low acoustic impedance; and
at least a portion of the support and at least a portion of the piezoelectric layer face each other across the acoustic reflection film.

9. An acoustic wave device comprising:
a piezoelectric layer made of lithium niobate;
a first comb-shaped electrode on the piezoelectric layer, including a first busbar and a plurality of first electrode fingers each including one end connected to the first busbar, and being connected to an input potential;
a second comb-shaped electrode on the piezoelectric layer, including a second busbar and a plurality of second electrode fingers each including one end connected to the second busbar and being interdigitated with the plurality of first electrode fingers, and being connected to an output potential; and
a reference potential electrode connected to a reference potential and including a plurality of third electrode fingers on the piezoelectric layer and aligned with the first electrode fingers and the second electrode fingers in a direction in which the first electrode fingers and the second electrode fingers are arranged, and a connection electrode connecting adjacent third electrode fingers; wherein
an order in which a first electrode finger, a second electrode finger, and a third electrode finger are arranged is such that, starting from the first electrode finger, the first electrode finger, the third electrode finger, the second electrode finger, and the third electrode finger define one period;
a direction in which the first electrode fingers, the second electrode fingers, and the third electrode fingers extend is an electrode finger extending direction, and a region where the first electrode fingers and the second electrode fingers overlap each other when viewed from a direction orthogonal or substantially orthogonal to the electrode finger extending direction is an intersection region; and
Ap/px≥about 5, where Ap is an intersection width of the intersection region along the electrode finger extending direction and px is a center-to-center distance between adjacent first and third electrode fingers or a center-to-center distance between adjacent second and third electrode fingers.

10. The acoustic wave device according to claim 9, wherein the acoustic wave device is structured to excite a plate wave.

11. The acoustic wave device according to claim 9, wherein the acoustic wave device is structured to excite a thickness-shear mode bulk wave.

12. An acoustic wave device comprising:
a piezoelectric layer made of lithium niobate with Euler angles (φ, θ, ψ) within a range of Expression (1), Expression (2), or Expression (3):
(within a range of 0°±10°, 0° to 25°, any ψ) Expression (1);
(within a range of 0°±10°, 25° to 100°, 0° to 75° [(1-(θ-50)²/2500)]^{1/2} or 180°-75° [(1−(θ-50)²/2500)]^{1/2} to 180°) Expression (2); and
(within a range of 0°±10°, 180°-40° [(1−(ψ-90)²/8100)]^{1/2} to 180°, any ψ) Expression (3);
a first comb-shaped electrode on the piezoelectric layer, including a first busbar and a plurality of first electrode fingers each including one end connected to the first busbar, and being connected to an input potential;
a second comb-shaped electrode on the piezoelectric layer, including a second busbar and a plurality of second electrode fingers each including one end connected to the second busbar and being interdigitated with the plurality of first electrode fingers, and being connected to an output potential; and
a reference potential electrode connected to a reference potential and including a plurality of third electrode fingers on the piezoelectric layer and aligned with the first electrode fingers and the second electrode fingers in a direction in which the first electrode fingers and the second electrode fingers are arranged, and a connection electrode connecting adjacent third electrode fingers; wherein
an order in which a first electrode finger, a second electrode finger, and a third electrode finger are arranged is such that, starting from the first electrode finger, the first electrode finger, the third electrode finger, the second electrode finger, and the third electrode finger define one period;
when a direction in which the first electrode fingers, the second electrode fingers, and the third electrode fingers extend is an electrode finger extending direction, leading ends of the plurality of first electrode fingers and the plurality of second electrode fingers each face an electrode connected to one of the input potential, the output potential, and the reference potential, which is different from that of the electrode fingers, across a gap in the electrode finger extending direction; and
G/px≤about 0.5, where G is a gap length of each gap along the electrode finger extending direction and px is a center-to-center distance between adjacent first and third electrode fingers or a center-to-center distance between adjacent second and third electrode fingers.

13. The acoustic wave device according to claim 12, wherein the acoustic wave device is structured to excite a plate wave.

14. The acoustic wave device according to claim 12, wherein the acoustic wave device is structured to excite a thickness-shear mode bulk wave.

15. An acoustic wave device comprising:
a piezoelectric layer made of lithium niobate with Euler angles (φ, θ, ψ) within a range of Expression (1), Expression (2), or Expression (3):
(within a range of 0°±10°, 0° to 25°, any ψ) Expression (1);
(within a range of 0°±10°, 25° to 100°, 0° to 75° [(1-(θ-50)²/2500)]^{1/2} or 180°-75° [(1−(θ-50)²/2500)]^{1/2} to 180°) Expression (2); and
(within a range of 0°±10°, 180°-40° [(1−(ψ-90)²/8100)]^{1/2} to 180°, any ψ) Expression (3);
a first comb-shaped electrode on the piezoelectric layer and including a first busbar and a plurality of first electrode fingers each including one end connected to the first busbar;
a second comb-shaped electrode on the piezoelectric layer and including a second busbar and a plurality of second electrode fingers each including one end connected to the second busbar and being interdigitated with the plurality of first electrode fingers; and
a reference potential electrode connected to a reference potential and including a plurality of third electrode fingers on the piezoelectric layer and aligned with the first electrode fingers and the second electrode fingers in a direction in which the first electrode fingers and the second electrode fingers are arranged, and a connection electrode connecting adjacent third electrode fingers; wherein
the first comb-shaped electrode is connected to one of an input potential and an output potential, and the second comb-shaped electrode is connected to another of the input potential and the output potential;
an order in which a first electrode finger, a second electrode finger, and a third electrode finger are arranged is such that, starting from the first electrode finger, the first electrode finger, the third electrode finger, the second electrode finger, and the third electrode finger define one period;
leading ends of at least some of adjacent third electrode fingers, among all of the adjacent third electrode fingers, on a first busbar side are connected by the connection electrode; and
G-B gap length≤G-F gap length, where the G-B gap length is a distance between the connection electrode connecting the leading ends of the adjacent third electrode fingers on the first busbar side and the first busbar, and the G-F gap length is a distance between the connection electrode and a leading end of one of the second electrode fingers.

16. The acoustic wave device according to claim 15, wherein the acoustic wave device is structured to excite a plate wave.

17. An acoustic wave device comprising:
a piezoelectric layer made of lithium niobate with Euler angles (φ, θ, ψ) (within a range of 0°±5°, within a range of −8°±14°, within a range of) 90°±5°;
a first comb-shaped electrode on the piezoelectric layer, including a first busbar and a plurality of first electrode fingers each including one end connected to the first busbar, and being connected to an input potential;
a second comb-shaped electrode on the piezoelectric layer, including a second busbar and a plurality of second electrode fingers each including one end connected to the second busbar and being interdigitated with the plurality of first electrode fingers, and being connected to an output potential; and
a reference potential electrode connected to a reference potential and including a plurality of third electrode fingers on the piezoelectric layer and aligned with the first electrode fingers and the second electrode fingers in a direction in which the first electrode fingers and the second electrode fingers are arranged, and a connection electrode connecting adjacent third electrode fingers; wherein
an order in which a first electrode finger, a second electrode finger, and a third electrode finger are arranged is such that, starting from the first electrode finger, the first electrode finger, the third electrode finger, the second electrode finger, and the third electrode finger define one period;
when a direction in which the first electrode fingers, the second electrode fingers, and the third electrode fingers extend is an electrode finger extending direction, leading ends of the plurality of first electrode fingers and the plurality of second electrode fingers each face an electrode connected to one of the input potential, the output potential, and the reference potential, which is different from that of the electrode fingers, across a gap in the electrode finger extending direction; and
G/px≥about 1, where G is a gap length of each gap along the electrode finger extending direction and px is a center-to-center distance between adjacent first and third electrode fingers or a center-to-center distance between adjacent second and third electrode fingers.

18. The acoustic wave device according to claim 17, wherein the acoustic wave device is structured to excite a plate wave.

19. An acoustic wave device comprising:
a piezoelectric layer made of lithium niobate with Euler angles (φ, θ, ψ) (within a range of 0°±5°, within a range of −8°±14°, within a range of) 90°±5°;
a first comb-shaped electrode on the piezoelectric layer and including a first busbar and a plurality of first electrode fingers each including one end connected to the first busbar;
a second comb-shaped electrode on the piezoelectric layer and including a second busbar and a plurality of second electrode fingers each including one end connected to the second busbar and being interdigitated with the plurality of first electrode fingers; and
a reference potential electrode connected to a reference potential and including a plurality of third electrode fingers on the piezoelectric layer and aligned with the first electrode fingers and the second electrode fingers in a direction in which the first electrode fingers and the second electrode fingers are arranged, and a connection electrode connecting adjacent third electrode fingers; wherein
the first comb-shaped electrode is connected to one of an input potential and an output potential, and the second comb-shaped electrode is connected to another of the input potential and the output potential;
an order in which a first electrode finger, a second electrode finger, and a third electrode finger are arranged is such that, starting from the first electrode finger, the first electrode finger, the third electrode finger, the second electrode finger, and the third electrode finger define one period;
leading ends of at least some of the adjacent third electrode fingers, among all of the adjacent third electrode fingers, on a first busbar side are connected by the connection electrode; and
G-B gap length>G-F gap length, where the G-B gap length is a distance between the connection electrode connecting the leading ends of adjacent third electrode fingers on the first busbar side and the first busbar, and the G-F gap length is a distance between the connection electrode and a leading end of one of the second electrode fingers on the first busbar side.

20. The acoustic wave device according to claim 19, wherein the acoustic wave device is structured to excite a plate wave.
